(19) United States
(12) Patent Application Publication
(10) Pub. No.: US 2026/0123143 A1
(43) Pub. Date: Apr. 30, 2026

(54) DISPLAY PANEL AND ELECTRONIC DEVICE INCLUDING THE SAME

(71) Applicant: Samsung Display Co., LTD., Yongin-si (KR)

(72) Inventors: Gyujeong Lee, Yongin-si (KR); Hyungil Jeon, Yongin-si (KR); Changil Tae, Yongin-si (KR)

(21) Appl. No.: 19/357,378

(22) Filed: Oct. 14, 2025

(30) Foreign Application Priority Data
Oct. 28, 2024 (KR) 10-2024-0148964

(51) Int. Cl. H10H 29/49; H10H 29/39

(52) U.S. Cl. CPC H10H 29/49; H10H 29/39

(57) ABSTRACT

A display panel includes a substrate including a plurality of island areas and a plurality of bridge areas connecting neighboring island areas to each other, a plurality of pixels arranged in the plurality of island areas, a plurality of wires arranged in the plurality of bridge areas, a first organic layer covering the plurality of pixels, the plurality of wires, and a side surface of the substrate, a first electrode layer covering the first organic layer and defining a plurality of first openings to overlap the plurality of pixels, a second organic layer covering an upper surface and a side surface of the first electrode layer, and a second electrode layer covering the second organic layer and defining a plurality of second openings to overlap the plurality of pixels.

This application claims priority to Korean Patent Application No. 10-2024-0148964, filed on October 28, 2024, and all the benefits accruing therefrom under 35 U.S.C. §119, the content of which in its entirety is herein incorporated by reference.

### BACKGROUND

### 1. Field

Embodiments relate to a display panel and an electronic device including the same, and more particularly, to a flexible display panel and an electronic device including the same.

### 2. Description of the Related Art

With the development of display panels for visually displaying electrical signals, a variety of electronic devices with excellent characteristics, such as thinness, light weight, and low power consumption, are being introduced. For example, electronic devices may include flexible display panels that are foldable or rollable into a roll shape. Recently, research and development are being actively conducted on various electronic devices including stretchable display panels that may be changed into various forms.

### SUMMARY

Embodiments include a display panel, e.g., a flexible display panel, and an electronic device including the same.

Additional features will be set forth in part in the description which follows and, in part, will be apparent from the description, or may be learned by practice of the presented embodiments of the disclosure.

In embodiments, a display panel includes a substrate including a plurality of island areas and a plurality of bridge areas connecting neighboring island areas among the plurality of island areas to each other, a plurality of pixels arranged in the plurality of island areas, a plurality of wires arranged in the plurality of bridge areas, a first organic layer covering the plurality of pixels, the plurality of wires, and a side surface of the substrate, a first electrode layer covering an upper surface and a side surface of the first organic layer, and defining a plurality of first openings to overlap the plurality of pixels in a plan view, a second organic layer covering an upper surface and a side surface of the first electrode layer, and a second electrode layer covering an upper surface and a side surface of the second organic layer, and defining a plurality of second openings to overlap the plurality of pixels in the plan view.

In an embodiment, the second electrode layer may include a plurality of first electrode cells arranged in a first direction, and a plurality of second electrode cells arranged in a second direction crossing the first direction, and the first electrode layer may include a plurality of connection electrodes connecting neighboring second electrode cells among the plurality of second electrode cells.

In an embodiment, among the plurality of first electrode cells, first electrode cells neighboring in the first direction may be provided integrally.

In an embodiment, the plurality of first electrode cells and the plurality of second electrode cells may be spaced apart from each other.

In an embodiment, the connection electrode may cross a first electrode cell of the plurality of first electrode cells to be electrically separated by the second organic layer from the first electrode cell, and may be electrically connected to overlapping second electrode cells among the plurality of second electrode cells through contact holes that penetrate the second organic layer.

In an embodiment, the second electrode layer may include a first part extending along an edge of each of the plurality of island areas in the plan view, and a second part extending along each of the plurality of bridge areas in the plan view.

In an embodiment, the second part may be electrically connected to the first electrode layer through a contact hole that penetrates the second organic layer.

In an embodiment, the second part may define a third opening exposing the upper surface of the second organic layer, and the second electrode layer may further include an auxiliary electrode disposed within a second opening among the plurality of second openings and a first auxiliary wire disposed within the third opening.

In an embodiment, the first electrode layer may further include a second auxiliary wire connected to the auxiliary electrode and the first auxiliary wire.

In an embodiment, each of the plurality of bridge areas may have a meandering shape.

In embodiments, a display panel includes a substrate including a plurality of island areas and a plurality of bridge areas connecting neighboring island areas among the plurality of island areas to each other, a display layer including a plurality of pixels arranged in the plurality of island areas and a plurality of wires arranged in the plurality of bridge areas, an input detection layer covering an upper surface and a side surface of the display layer, and including a plurality of first touch electrodes extending in a first direction and a plurality of second touch electrodes extending in a second direction crossing the first direction, wherein the plurality of first touch electrodes and the plurality of second touch electrodes cover a side surface of the substrate along edges of the plurality of island areas and edges of the plurality of bridge areas, respectively.

In an embodiment, each of the plurality of first touch electrodes may include a plurality of first electrode cells arranged in the first direction, each of the plurality of second touch electrodes may include a plurality of second electrode cells arranged in the second direction and a plurality of connection electrodes connecting neighboring second electrode cells among the plurality of second electrode cells, and the plurality of first electrode cells and the plurality of connection electrode may be arranged in different layers.

In an embodiment, among the plurality of first electrode cells, first electrode cells neighboring in the first direction may be provided integrally.

In an embodiment, the plurality of first electrode cells and the plurality of second electrode cells may be spaced apart from each other.

In an embodiment, the display panel may further include an insulating layer disposed between a connection electrode among the plurality of connection electrodes and the plurality of first electrode cells, and between the connection electrode and the plurality of second electrode cells, wherein the connection electrode may cross a first electrode cell of the plurality of first electrode cells to be electrically separated by the insulating layer, and electrically connected to overlapping second electrode cells among the plurality of second electrode cells through contact holes that penetrate the insulating layer.

In an embodiment, each of the plurality of first touch electrodes and each of the plurality of second touch electrodes may include a first part extending along an edge of each of the plurality of island areas and a second part extending along each of the plurality of bridge areas.

In an embodiment, each of the plurality of second touch electrodes may include a plurality of electrode cells arranged in the second direction and a connection electrode connecting neighboring electrode cells among the plurality of electrode cells, the input detection layer may further include an insulating layer disposed between the connection electrode and the plurality of first touch electrodes, and between the connection electrode and the plurality of second touch electrodes, and the second part of the second touch electrode overlapping the connection electrode among the plurality of second touch electrodes may be electrically connected to the connection electrode through a contact hole that penetrates the insulating layer.

In an embodiment, the first part may define a first opening overlapping the plurality of pixels.

In an embodiment, the second part may define a second opening overlapping the plurality of bridge areas, and the input detection layer may include an auxiliary electrode disposed within the first opening, a first auxiliary wire disposed within the second opening, and a second auxiliary wire connecting the auxiliary electrode to the first auxiliary wire.

In an embodiment, each of the plurality of bridge areas may have a meandering shape.

In embodiments, an electronic device includes a display panel that is stretchable, wherein the display panel includes a substrate including a plurality of island areas and a plurality of bridge areas connecting neighboring island areas among the plurality of island areas to each other, a plurality of pixels arranged in the plurality of island areas, a plurality of wires arranged in the plurality of bridge areas, a first organic layer covering the plurality of pixels, the plurality of wires, and a side surface of the substrate, a first electrode layer covering an upper surface and a side surface of the first organic layer, and defining a plurality of first openings to overlap the plurality of pixels in a plan view, a second organic layer covering an upper surface and a side surface of the first electrode layer, and a second electrode layer covering an upper surface and a side surface of the second organic layer, and defining a plurality of second openings to overlap the plurality of pixels in the plan view.

Other features and advantages than those described above will become apparent from the following drawings, claims, and detailed description of the disclosure

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of a display panel;

FIGS. 2A and 2B are perspective views showing the display panel of FIG. 1 stretched in a first direction;

FIG. 2C is a perspective view showing the display panel of FIG. 1 stretched in a second direction;

FIG. 2D is a perspective view showing the display panel of FIG. 1 stretched in both the first and second directions;

FIG. 2E is a perspective view showing the display panel of FIG. 1 stretched in a third direction;

FIGS. 3A to 3C each are equivalent circuit diagrams showing an embodiment of a pixel included in a display panel;

FIGS. 4A to 4C each are schematic plan views showing an embodiment of a portion of a display area of a display panel;

FIGS. 5A to 5D each are schematic cross-sectional views showing an embodiment of a light-emitting diode of a display panel;

FIGS. 6A and 6B each are schematic plan views showing an embodiment of touch electrodes and connection electrodes;

FIG. 7 is a schematic plan view showing an embodiment of a portion of a display panel;

FIG. 8 is a schematic cross-sectional view of the display panel taken along line IV-IV′ of FIG. 7;

FIGS. 9A and 9B each are schematic plan views showing an embodiment of a portion of a display panel;

FIG. 10A is a schematic cross-sectional view of the display panel taken along line V-V′ of FIG. 9A;

FIG. 10B is a schematic cross-sectional view of the display panel taken along line VI-VI′ of FIG. 9A;

FIG. 11 is a schematic plan view showing an embodiment of a portion of a display panel;

FIG. 12 is a schematic cross-sectional view showing an embodiment of a portion of a display panel;

FIG. 13A is a schematic perspective view showing an embodiment of an electronic device including a display panel;

FIG. 13B is a block diagram showing an embodiment of an electronic device including a display panel; and

FIGS. 14A to 14G each are schematic perspective views showing embodiments of an electronic device including a display panel.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

Various modifications may be applied to the illustrated embodiments, and particular embodiments will be illustrated in the drawings and described in the detailed description section. The effect and features of the illustrated embodiments, and a method to achieve the same, will be clearer referring to the detailed descriptions below with the drawings. However, the illustrated embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and redundant descriptions thereof are omitted.

In the specification, it will be understood that although the terms first, second, etc. may be used herein to describe various elements, these elements should not be limited by these terms. These elements are only used to distinguish one element from another.

In the specification, as used herein, the singular forms "a," "an," and "the" are intended to include the plural forms as well, unless the context clearly indicates otherwise.

In the specification, it will be further understood that the terms "comprises" and/or "comprising" used herein specify the presence of stated features or elements, but do not preclude the presence or addition of one or more other features or components.

In the specification, it will be understood that when an element, such as a layer, a film, a region, or a plate, is referred to as being "on" another element, the element may be directly on the other element or intervening elements may be thereon.

In the specification, it will be understood that when a layer, region, or element is referred to as being "connected to" another layer, region, or element, it may be directly connected to the other layer, region, or component or indirectly connected to the other layer, region, or component via intervening layers, regions, or components. For example, in the specification, when a layer, region, or component is referred to as being electrically connected to another layer, region, or component, it may be directly electrically connected to the other layer, region, or component or indirectly electrically connected to the other layer, region, or component via intervening layers, regions, or components.

In the specification, the expression such as "A and/or B" may include A, B, or A and B. The expression such as "at least one of A and B" may include A, B, or A and B.

In the specification, the x direction, the y direction, and the z direction are not limited to the directions along three axes of the rectangular coordinate system, and may be interpreted in a broader sense. For example, the x direction, the y direction, and the z direction may be perpendicular to one another, or may represent different directions that are not perpendicular to one another.

In the specification, an "upper surface" of a substrate may refer to a surface at a side where a display element is disposed, and a "lower surface" of the substrate may refer to a surface opposite to the upper surface. A "side surface" of a substrate may refer to a surface connecting between an upper surface and a lower surface of the substrate. A "lower surface" of each component disposed on a substrate may refer to a surface in a substrate direction, and an "upper surface" of the component may refer to a surface opposite to the lower surface of the component. A "side surface" of each component may refer to a surface connecting between an upper surface and a lower surface of the component.

In the specification, when it is referred to as "in a plan view," this means when an object part is viewed from the top, and when it is referred to as "in a cross-sectional view," it means when the cross-section where the object part is cut vertically is viewed from the side.

In the specification, when a first component is referred to as "overlapping" a second component, it means that the first component is disposed above or below the second component at least partially overlapping each other in a plan view.

In the specification, when an illustrative embodiment may be implemented differently, a specific process order may be performed differently from the described order. For example, two consecutively described processes may be performed substantially at the same time or performed in an order opposite to the described order.

Sizes of elements in the drawings may be exaggerated for convenience of explanation. For example, since sizes and thicknesses of elements in the drawings are arbitrarily illustrated for convenience of explanation, the following disclosure is not limited thereto.

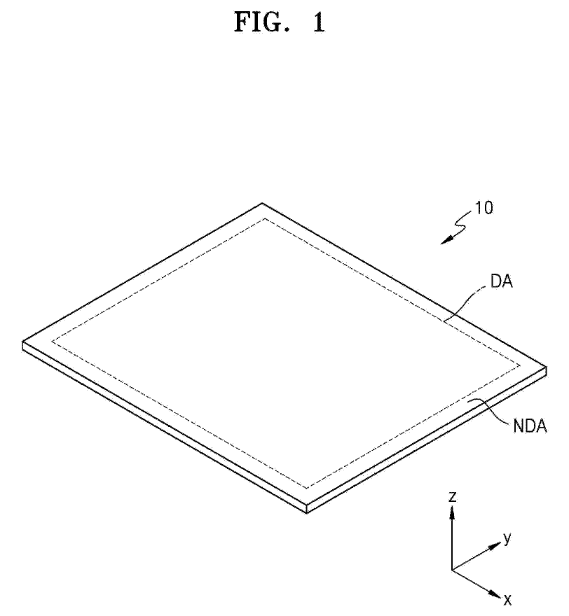

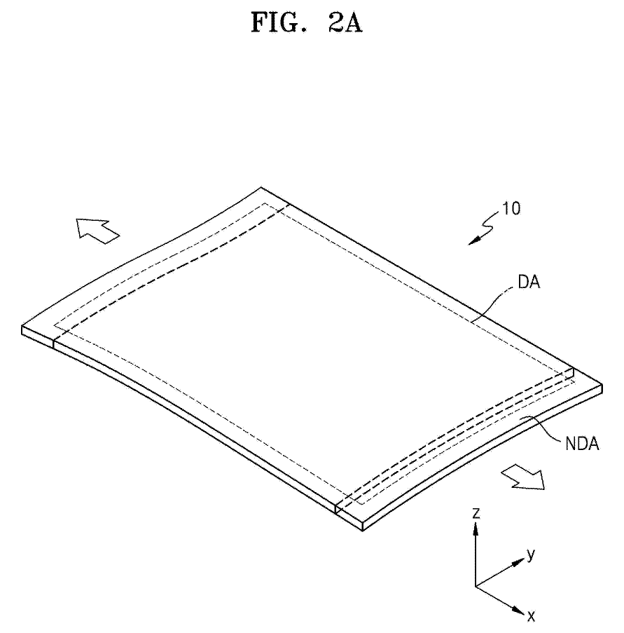

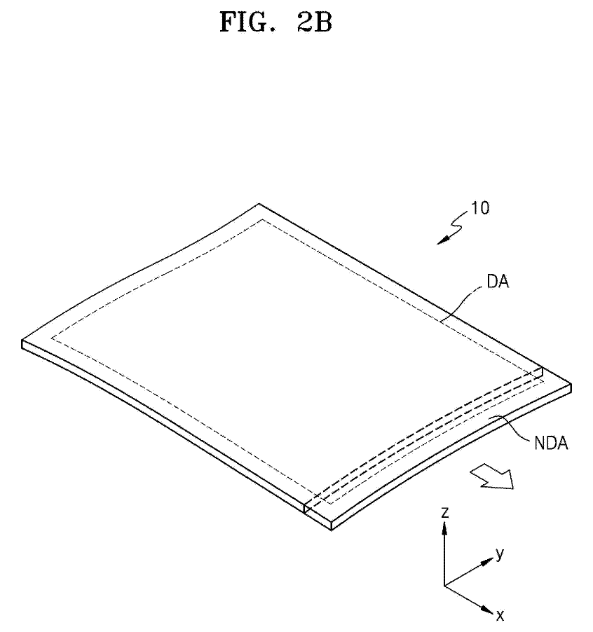

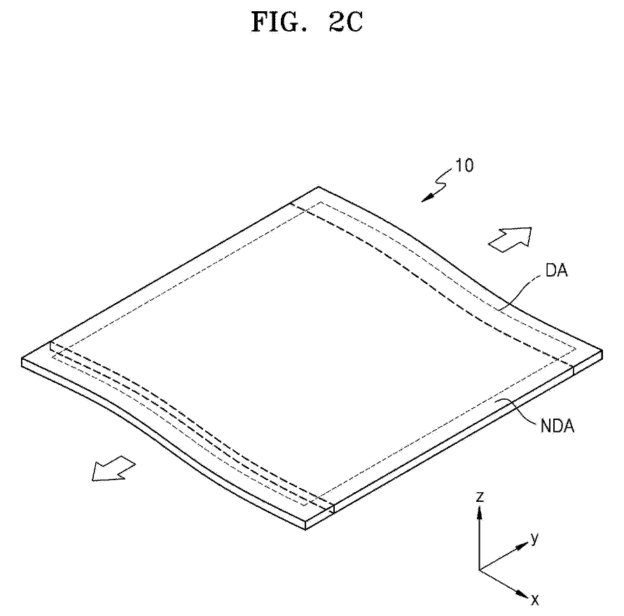

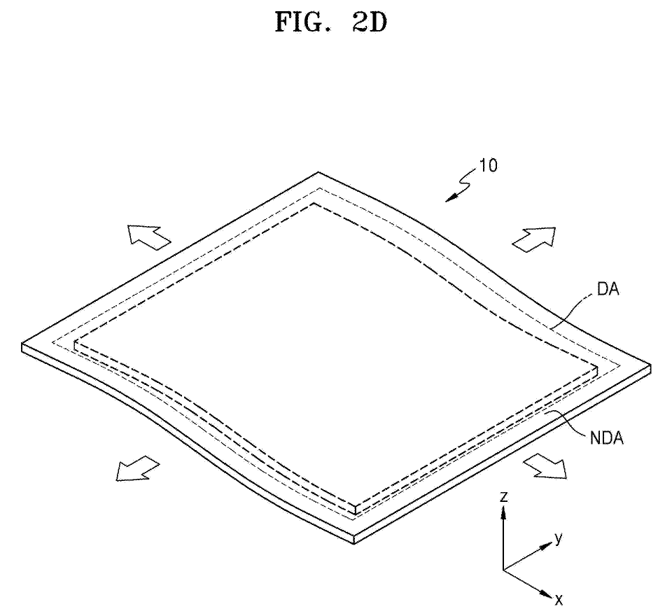

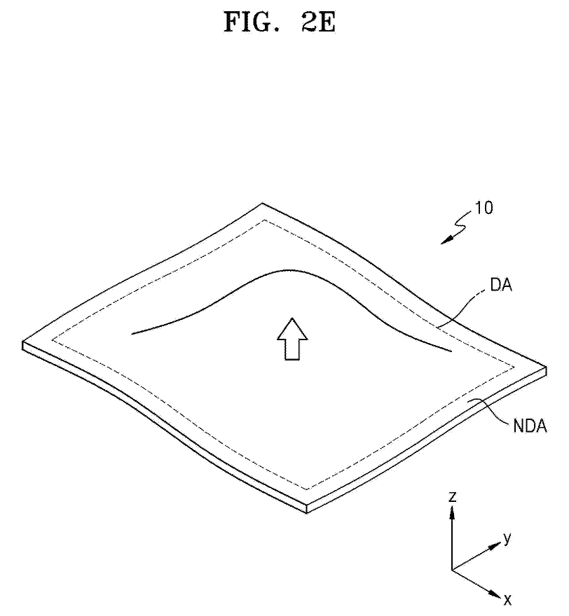

FIG. 1 is a schematic perspective view of an embodiment of a display panel 10. FIGS. 2A and 2B are perspective views showing the display panel 10 of FIG. 1 stretched in a first direction. FIG. 2C is a perspective view showing the display panel 10 of FIG. 1 stretched in a second direction. FIG. 2D is a perspective view showing the display panel 10 of FIG. 1 stretched in both the first and second directions. FIG. 2E is a perspective view showing the display panel 10 of FIG. 1 stretched in a third direction.

Referring to FIG. 1, the display panel 10 may include a display area DA and a non-display area NDA. The display area DA may include a plurality of pixels. The display panel 10 may provide a predetermined image by light emitted from the plurality of pixels. The non-display area NDA may be disposed outside the display area DA. The non-display area NDA may surround an entirety of the display area DA.

The display panel 10 may stretch or shrink in various directions. The display panel 10 may be stretched in a first direction (e.g., a +x direction and/or a -x direction) by an external force applied by an external object or a user. In an embodiment, as illustrated in FIGS. 2A and 2B, the display area DA and/or the non-display area NDA of the display panel 10 may be stretched in the first direction (e.g., the +x direction and/or the -x direction). In an embodiment, the display area DA and/or the non-display area NDA of the display panel 10 may be stretched in the +x direction and the -x direction, as illustrated in FIG. 2A, or may be stretched in the +x direction with one side of the display panel 10 fixed, as illustrated in FIG. 2B, for example.

The display panel 10 may be stretched in a second direction (e.g., a +y direction and/or a -y direction) by an external force applied by an external object or a user. In an embodiment, as illustrated in FIG. 2C, the display area DA and/or the non-display area NDA of the display panel 10 may be stretched in the +y direction and the -y direction. In another embodiment, the display area DA and/or the non-display area NDA of the display panel 10 may be stretched in the +y direction or the -y direction with one side of the display panel 10 fixed.

The display panel 10 may be stretched by an external force applied by an external object or a part of a human body in a plurality of directions, e.g., the first direction (e.g., the +x direction and/or the -x direction) and in the second direction (e.g., the +y direction and/or the -y direction). As illustrated in FIG. 2D, the display area DA and/or the non-display area NDA of the display panel 10 may be stretched in the ±x direction and the ±y direction.

The display panel 10 may be stretched in a third direction (e.g., a +z direction or a −z direction) by an external force applied by an external object or a part of a human body. In an embodiment, FIG. 2E illustrates that a part of the display panel 10, e.g., a partial area of the display area DA, protrudes in the z direction. In another embodiment, a part of the display panel 10, e.g., a partial area of the display area DA may protrude in the +z direction or may be recessed in the -z direction.

FIGS. 2A to 2E illustrate that the display panel 10 is stretched in the first direction, the second direction, and/or the third direction, but the disclosure is not limited thereto. In another embodiment, the display panel 10 may be transformed into various amorphous shapes by bending or twisting about two or more axes.

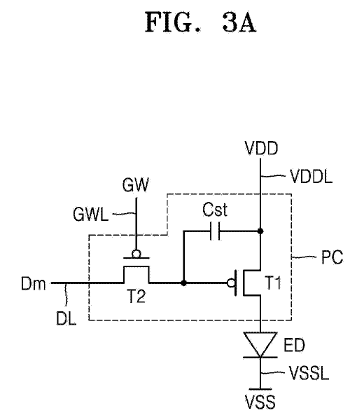

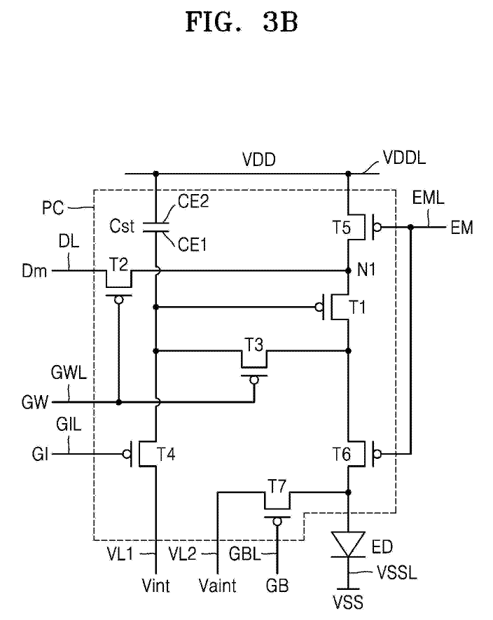

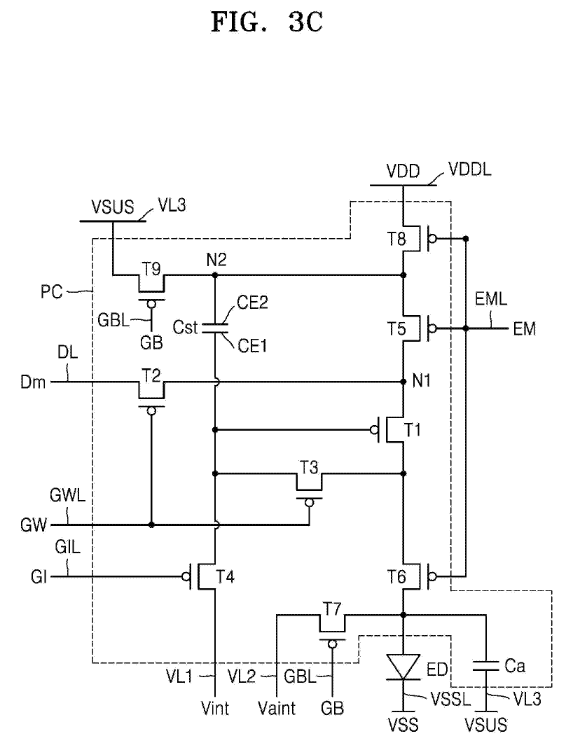

FIGS. 3A to 3C each are equivalent circuit diagrams showing an embodiment of a pixel included in a display panel.

Referring to FIG. 3A, one pixel may include a light-emitting diode ED and a pixel circuit PC for controlling luminance of the light-emitting diode ED. The light-emitting diode ED may be electrically connected to the pixel circuit PC, and the pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL and a second voltage line VSSL.

The second transistor T2 may be electrically connected to the scan signal line GWL and the data line DL. The scan signal line GWL may provide a scan signal GW to a gate electrode of the second transistor T2. The second transistor T2 may transmit a data signal Dm input through the data line DL to the first transistor T1, in response to the scan signal GW input through the scan signal line GWL.

The storage capacitor Cst may be electrically connected to the second transistor T2 and the first voltage line VDDL, and may store a voltage corresponding to a difference between the voltage transmitted from the second transistor T2 and a first power voltage VDD received through the first voltage line VDDL.

The first transistor T1, as a driving transistor, may control a driving current flowing in the light-emitting diode ED. The first transistor T1 may be connected to the first voltage line VDDL and the storage capacitor Cst. The first transistor T1 may control the driving current flowing from the first voltage line VDDL to the light-emitting diode ED, in response to a voltage value stored in the storage capacitor Cst. The light-emitting diode ED may emit light with a predetermined luminance depending on the driving current. A first electrode of the light-emitting diode ED may be electrically connected to the first transistor T1, and a second electrode of the light-emitting diode ED may be electrically connected to the second voltage line VSSL through which a second power voltage VSS is supplied.

FIG. 3A illustrates that the pixel circuit PC includes two transistors and one storage capacitor, but in another embodiment, the pixel circuit PC may include three or more transistors and one storage capacitor.

Referring to FIG. 3B, the pixel circuit PC may include the first transistor T1, the second transistor T2, a third transistor T3, a fourth transistor T4, a fifth transistor T5, a sixth transistor T6, a seventh transistor T7, and the storage capacitor Cst.

The pixel circuit PC electrically connected to signal lines and voltage lines. The signal lines may include the scan signal line GWL, a bypass control line GBL, an initialization control line GIL, a gate line such as an emission control line EML, and the data line DL. The voltage lines may include first and second initialization voltage lines VL1 and VL2, the first voltage line VDDL, and the second voltage line VSSL.

The first voltage line VDDL may transmit the first power voltage VDD to the first transistor T1. The first initialization voltage line VL1 may transmit a first initialization voltage Vint for initializing the first transistor T1 to the pixel circuit PC. The second initialization voltage line VL2 may transmit a second initialization voltage Vaint for initializing a first electrode of the light-emitting diode ED, to the pixel circuit PC.

The first transistor T1 may be electrically connected to the first voltage line VDDL via the fifth transistor T5, and to the light-emitting diode ED via the sixth transistor T6. The first transistor T1, which serves as a driving transistor, may receive the data signal Dm according to a switching operation of the second transistor T2 and supply a driving current to the light-emitting diode ED.

The second transistor T2, as a data write transistor, may be electrically connected to the scan signal line GWL and the data line DL. The second transistor T2 may be electrically connected to the first voltage line VDDL via the fifth transistor T5. The second transistor T2 may be turned on in response to the scan signal GW received through the scan signal line GWL to perform a switching operation of transmitting the data signal Dm received through the data line DL to a first node N1.

The third transistor T3 may be electrically connected to the scan signal line GWL and electrically connected to the light-emitting diode ED via the sixth transistor T6. The third transistor T3 may be turned on in response to the scan signal GW received through the scan signal line GWL to be diode-connected to the first transistor T1.

The fourth transistor T4, as a first initialization transistor, may be electrically connected to the initialization control line GIL and the first initialization voltage line VL1. The fourth transistor T4 may be turned on in response to an initialization control signal GI received through the initialization control line GIL to transmit the first initialization voltage Vint received through the first initialization voltage line VL1 to a gate electrode of the first transistor T1, thereby initializing the voltage of the gate electrode of the first transistor T1. The initialization control signal GI may correspond to a scan signal of another pixel circuit disposed in the previous row of the corresponding pixel circuit PC.

The fifth transistor T5 may be an operation control transistor, and the sixth transistor T6 may be an emission control transistor. The fifth transistor T5 and the sixth transistor T6 may be electrically connected to the emission control line EML, and may be simultaneously turned on in response to an emission control signal EM received through the emission control line EML to form a current path through which a driving current flows in a direction from the first voltage line VDDL to the light-emitting diode ED. The first electrode of the light-emitting diode ED may be electrically connected to the first transistor T1 via the sixth transistor T6, and the second electrode of the light-emitting diode ED may be electrically connected to the second voltage line VSSL that supplies the second power voltage VSS.

The seventh transistor T7, as a second initialization transistor, may be electrically connected to the bypass control line GBL, the second initialization voltage line VL2, and the sixth transistor T6. The seventh transistor T7 may be turned on in response to a bypass control signal GB received through the bypass control line GBL, and may transmit the second initialization voltage Vaint through the second initialization voltage line VL2 to the first electrode of the light-emitting diode ED, thereby initializing the first electrode of the light-emitting diode ED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and retain a voltage corresponding to a difference in voltage between opposite ends of the first voltage line VDDL and the gate electrode of the first transistor T1, thereby retaining the voltage applied to the gate electrode of the first transistor T1.

Referring to FIG. 3C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel circuit PC may be electrically connected to signal lines and voltage lines. The signal lines may include the scan signal line GWL, the bypass control line GBL, the initialization control line GIL, the gate line such as the emission control line EML, and the data line DL. The voltage lines may include the first and second initialization voltage lines VL1 and VL2, a sustain voltage line VL3, the first voltage line VDDL, and the second voltage line VSSL.

The first voltage line VDDL may transmit the first power voltage VDD to the first transistor T1. The first initialization voltage line VL1 may transmit the first initialization voltage Vint for initializing the first transistor T1 to the pixel circuit PC. The second initialization voltage line VL2 may transmit the second initialization voltage Vaint for initializing the first electrode of the light-emitting diode ED to the pixel circuit PC. The sustain voltage line VL3 may provide a sustain voltage VSUS to a second node N2, e.g., the second electrode CE2 of the storage capacitor Cst, in an initialization section and a data write section.

The first transistor T1 may be electrically connected to the first voltage line VDDL via the fifth transistor T5 and the eighth transistor T8, and to the light-emitting diode ED via the sixth transistor T6. The first transistor T1, which serves as a driving transistor, may receive the data signal Dm according to the switching operation of the second transistor T2, and supply a driving current to the light-emitting diode ED.

The second transistor T2 may be electrically connected to the scan signal line GWL and the data line DL, and to the first voltage line VDDL via the fifth transistor T5 and the eighth transistor T8. The second transistor T2 may be turned on in response to the scan signal GW received through the scan signal line GWL to perform a switching operation of transmitting the data signal Dm received through the data line DL to the first node N1.

The third transistor T3 may be electrically connected to the scan signal line GWL, and to the light-emitting diode ED via the sixth transistor T6. The third transistor T3 may be turned on in response to the scan signal GW received through the scan signal line GWL to be diode-connected to the first transistor T1, thereby compensating for a threshold voltage of the first transistor T1.

The fourth transistor T4 may be electrically connected to the initialization control line GIL and the first initialization voltage line VL1, and may be turned on in response to the initialization control signal GI received through the initialization control line GIL to transmit the first initialization voltage Vint received through the first initialization voltage line VL1 to the gate electrode of the first transistor T1, thereby initializing the voltage of the gate electrode of the first transistor T1. The initialization control signal GI may correspond to a scan signal of another pixel circuit disposed in the previous row of the corresponding pixel circuit PC.

The fifth transistor T5, the sixth transistor T6, and the eighth transistor T8 may be electrically connected to the emission control line EML, and may be simultaneously turned on in response to the emission control signal EM received through the emission control line EML to form a current path through which a driving current flows in a direction from the first voltage line VDDL to the light-emitting diode ED. The first electrode of the light-emitting diode ED may be electrically connected to the first transistor T1 via the sixth transistor T6, and the second electrode of the light-emitting diode ED may be electrically connected to the second voltage line VSSL that supplies the second power voltage VSS.

The seventh transistor T7, as a second initialization transistor, may be electrically connected to the bypass control line GBL, the second initialization voltage line VL2, and the sixth transistor T6. The seventh transistor T7 may be turned on in response to the bypass control signal GB received through the bypass control line GBL, and may transmit the second initialization voltage Vaint through the second initialization voltage line VL2 to the first electrode of the light-emitting diode ED, thereby initializing the first electrode of the light-emitting diode ED.

The ninth transistor T9 may be electrically connected to the bypass control line GBL, the second electrode CE2 of the storage capacitor Cst, and the sustain voltage line VL3. The ninth transistor T9 may be turned on in response to the bypass control signal GB received through the bypass control line GBL, and may transmit the sustain voltage VSUS to the second node N2, e.g., the second electrode CE2 of the storage capacitor Cst, in the initialization section and the data write section.

The eighth transistor T8 and the ninth transistor T9 may each be electrically connected to the second node N2, e.g., the second electrode CE2 of the storage capacitor Cst. In some embodiments, in the initialization section and the data write section, the eighth transistor T8 may be turned off and the ninth transistor T9 may be turned on, and in a light-emitting section, the eighth transistor T8 may be turned on and the ninth transistor T9 may be turned off.

The storage capacitor Cst may include the first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustain voltage line VL3, and the first electrode of the light-emitting diode ED. While the seventh transistor T7 and the ninth transistor T9 are turned on, the auxiliary capacitor Ca may store and retain a voltage corresponding to a difference in voltage between the first electrode of the light-emitting diode ED and the sustain voltage line VL3, thereby preventing an increase of black luminance when the sixth transistor T6 is turned off.

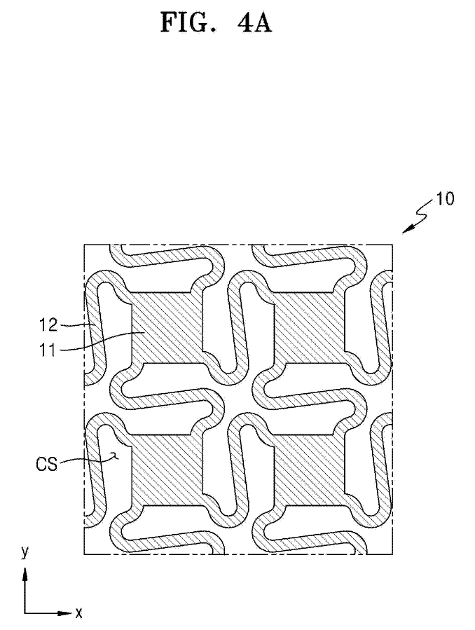

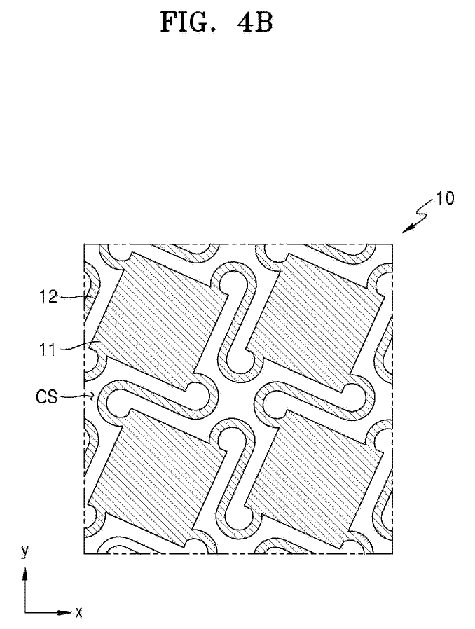

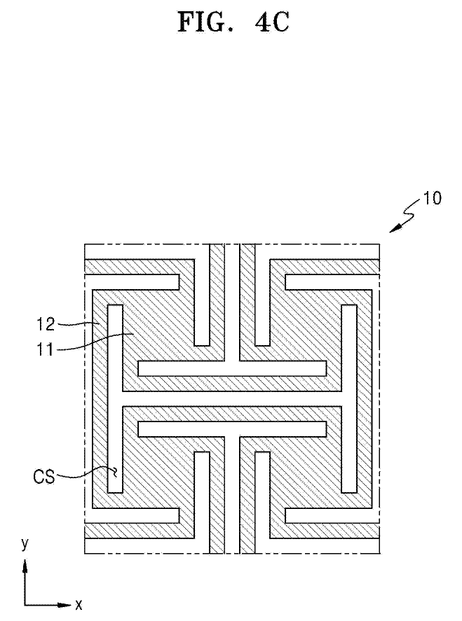

FIGS. 4A to 4C each are schematic plan views showing an embodiment of a portion of a display area of a display panel.

Referring to FIG. 4A, the display panel 10 may include, in the display area DA (refer to FIG. 1), a plurality of first island parts 11 that are spaced apart from each other in the first direction (e.g., the +x direction or the −x direction) and the second direction (e.g., the +y direction or the −y direction), and in the non-display area NDA (refer to FIG. 1), a plurality of first bridge parts 12 that are extended to first island parts 11 next (adjacent) to each other.

Each of the first island parts 11 may be extended to the first bridge parts 12. In an embodiment, each first island part 11 may be extended to four first bridge parts 12, for example. The two of the first bridge parts 12 may be arranged on the opposite sides of the first island part 11 in the first direction (e.g., the +x direction or the −x direction), and remaining (the other) two first bridge parts 12 may be arranged on the opposite sides of the first island part 11 in the second direction (e.g., the +y direction or the −y direction). In an embodiment, the four first bridge parts 12 may be extended to four sides of the first island part 11. The four first bridge parts 12 may be respectively arranged close to the corners of the first island part 11.

The first bridge parts 12 may be spaced apart from each other by an opening area CS disposed between the first bridge parts 12. The first bridge part 12 may have a meandering shape. In an embodiment, as illustrated in FIG. 4A, the first bridge part 12 may have a shape of an approximately ′alphabet S′, for example.

Referring to FIG. 4B, the display panel 10 may include, in the display area DA (refer to FIG. 1), a plurality of first island parts 11 that are spaced apart from each other in the first direction (e.g., the +x direction or the −x direction) and the second direction (e.g., the +y direction or the −y direction), and in the non-display area NDA (refer to FIG. 1), the first bridge parts 12 that are extended to first island parts 11 next (adjacent) to each other. The first bridge parts 12 may be spaced apart from each other by the opening area CS disposed between the first bridge parts 12.

In an embodiment, at least one of the sides of the first island part 11 may be tilted obliquely to the first direction (e.g., the +x direction or the −x direction) and/or the second direction (e.g., the +y direction or the −y direction). FIG. 4B illustrates that all four sides of the first island part 11 are tilted obliquely in the clockwise direction.

The first island part 11 may be extended to the first bridge parts 12. In an embodiment, the first island part 11 may be extended to four first bridge parts 12, for example. The two first bridge parts 12 may be arranged in the first direction (e.g., the +x direction or the −x direction) on the opposite sides of the first island part 11, and remaining (the other) two first bridge parts 12 may be arranged on the opposite sides of the first island part 11 in the second direction (e.g., the +y direction or the −y direction).

The first bridge part 12 may have a meandering shape. In an embodiment, as illustrated in FIG. 4B, the first bridge part 12 may have a shape of an approximately ′alphabet S′, for example.

In an embodiment, as illustrated in FIG. 4B, the first bridge part 12 may extend substantially parallel to a side of the first island part 11 next (adjacent) thereto. In an embodiment, the first bridge part 12 may have two round sections extended to first island parts 11 next (adjacent) to each other and a straight section extended to the round sections, for example. The straight section of the first bridge part 12 may extend substantially parallel to a side of the first island part 11 next (adjacent) thereto.

According to the arrangement of the first island part 11 and/or the structure of the first bridge part 12 described above, the area of the opening area CS illustrated in FIG. 4B may be relatively smaller than the area of the opening area CS illustrated in FIG. 4A. Accordingly, the display panel 10 in the embodiment illustrated in FIG. 4B may provide an image of a relatively high resolution.

Referring to FIG. 4C, the display panel 10 may include, in the display area DA (refer to FIG. 1), a plurality of first island parts 11 that are spaced apart from each other in the first direction (e.g., the +x direction or the −x direction) and the second direction (e.g., the +y direction or the −y direction), and in the non-display area NDA (refer to FIG. 1), the first bridge parts 12 that are extended to first island parts 11 next (adjacent) to each other.

Each of the first island parts 11 may be extended to the first bridge parts 12. In an embodiment, each first island part 11 may be extended to the four first bridge parts 12, for example. The two first bridge parts 12 may be arranged in the first direction (e.g., the +x direction or the −x direction) on the opposite sides of the first island part 11, and remaining (the other) two first bridge parts 12 may be arranged on the opposite sides of the first island part 11 in the second direction (e.g., the+ y direction or the −y direction). In an embodiment, the four first bridge parts 12 may be extended to four sides of the first island part 11. The four first bridge parts 12 may be respectively arranged close to the corners of the first island part 11.

The first bridge parts 12 may be spaced apart from each other by the opening area CS disposed between the first bridge parts 12. In an embodiment, the opening area CS having an approximately H shape and the opening area CS having an approximately I shape, which is obtained by rotating the H shape described above by 90°, may be alternately and repeatedly arranged in each of the first direction (e.g., the +x direction or the −x direction) and the second direction (e.g., the +y direction or the −y direction). While the opposite ends of each first bridge part 12 may be respectively extended to first island parts 11 next (adjacent) to each other, one side of each first bridge part 12 may be spaced apart, by the opening area CS, from one side of a neighboring (adjacent) first island part 11 and/or one side of another first bridge part 12.

In an embodiment, the display panel 10 may include, in the non-display area NDA (refer to FIG. 1), a plurality of second island parts that are spaced apart from each other in the first direction (e.g., the +x direction or the −x direction) and the second direction (e.g., the +y direction or the −y direction), and a plurality of second bridge parts that are extended to second island parts next (adjacent) to each other. Accordingly, the non-display area NDA of the display panel 10 may be stretched in various directions. Each of the second island part and the second bridge part may have a shape same as or similar to the first island part 11 and the first bridge part 12 of the display area DA described with reference to FIGS. 4A to 4C. In another embodiment, each of the second island part and the second bridge part of the non-display area NDA may have a shape different from the first island part 11 and the first bridge part 12 of the display area DA.

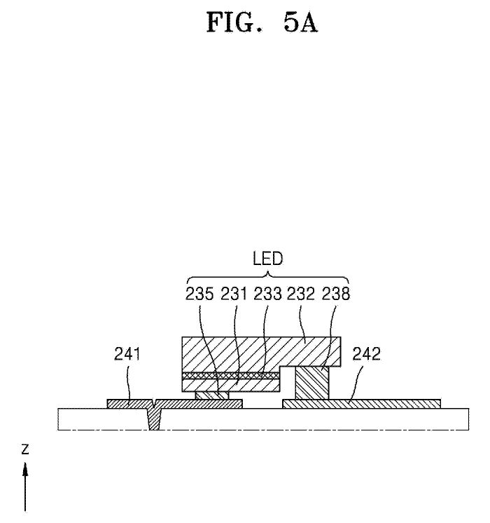

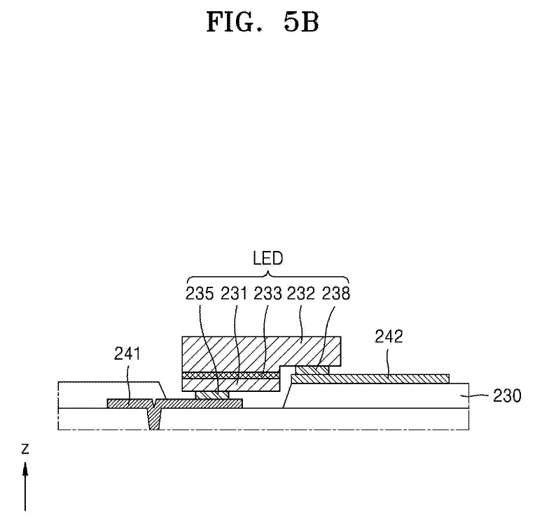

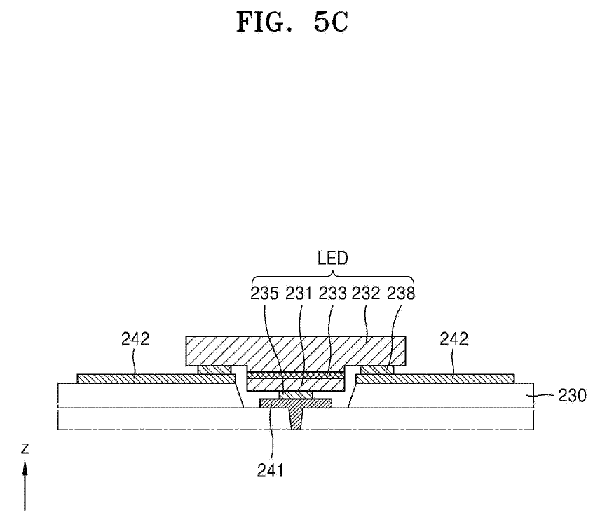

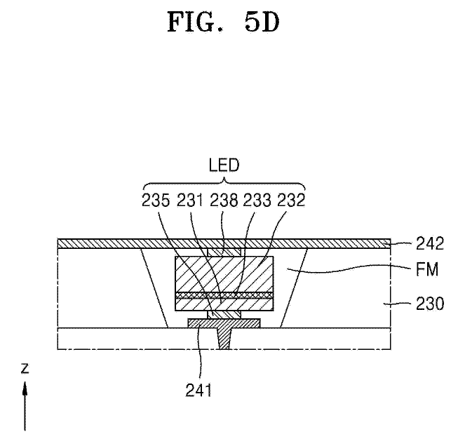

FIGS. 5A to 5D each are schematic cross-sectional views showing an embodiment of a light-emitting diode of a display panel.

Referring to FIG. 5A, a light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be electrically connected to a first electrode pad 241 and a second electrode pad 242 arranged in a same layer. The second electrode pad 242 may be a part of the second voltage line VSSL (refer to FIG. 5A) or may be a conductive layer electrically connected to the second voltage line VSSL (refer to FIG. 5A).

In some embodiments, the first semiconductor layer 231 may include a p-type semiconductor layer. The p-type semiconductor layer may include or consist of semiconductor materials having a composition of InₓAl_{y}Ga_{1-x-y}N (0 ≤ x ≤ 1, 0 ≤ y ≤ 1, and 0 ≤ (x+y) ≤ 1), e.g., GaN, AlN, AlGaN, InGaN, InN, InAlGaN, AlInN, etc., and may be doped with a p-type dopant, such as Mg, Zn, Ca, Sr, Ba, etc.

The second semiconductor layer 232 may include an n-type semiconductor layer. The n-type semiconductor layer may include or consist of semiconductor materials having a composition of InₓAl_{y}Ga_{1-x-y}N (0 ≤ x ≤ 1, 0 ≤ y ≤ 1, and 0 ≤ (x+y) ≤ 1), e.g., GaN, AlN, AlGaN, InGaN, InN, InAlGaN, AlInN, etc., and may be doped with an n-type dopant, such as Si, Ge, Sn, etc., for example.

The intermediate layer 233 is a region where electrons and holes recombine, and as electrons and holes recombine, the electrons and holes transition to a lower energy level and may generate light having a corresponding wavelength. The intermediate layer 233 may include a semiconductor material having a composition, e.g., InₓAl_{y}Ga_{1-x-y}N (0 ≤ x ≤ 1, 0 ≤ y ≤ 1, and 0 ≤ (x+y) ≤ 1), and may be formed in a single quantum well structure or a multi-quantum well (“MQW”) structure. Furthermore, the intermediate layer 233 may have a quantum wire structure or a quantum dot structure.

FIG. 5A illustrates that the first semiconductor layer 231 includes a p-type semiconductor layer, and that the second semiconductor layer 232 includes an n-type semiconductor layer, but the disclosure is not limited thereto. In another embodiment, the first semiconductor layer 231 may include an n-type semiconductor layer, and the second semiconductor layer 232 may include a p-type semiconductor layer.

FIG. 5A illustrates that the first electrode pad 241 and the second electrode pad 242 are arranged in a same layer, but the disclosure is not limited thereto. Referring to FIG. 5B, the first electrode pad 241 and the second electrode pad 242 may be disposed in different layers. In an embodiment, a bank layer 230 defining an opening that overlaps at least a part of the first electrode pad 241 may be disposed on the first electrode pad 241, and the second electrode pad 242 may be disposed on an upper surface of the bank layer 230, for example. The structure of the light-emitting diode LED illustrated in FIG. 5B is the same as the structure described above with reference to FIG. 5A.

In another embodiment, as illustrated in FIG. 5C, the second electrode pad 242 may be disposed on the opposite sides of the first electrode pad 241 in a cross-sectional view. The bank layer 230 may define an opening overlapping at least a part of the first electrode pad 241, and the second electrode pad 242 may be disposed around the opening of the bank layer 230. In some embodiments, in a plan view, the second electrode pad 242 may have a closed loop shape that surrounds an entirety of the opening of the bank layer 230 and/or the first electrode pad 241. The structure of the light-emitting diode LED illustrated in FIG. 5C is the same as the structure described above with reference to FIG. 5A.

FIGS. 5A to 5C illustrate that the first electrode 235 and the second electrode 238 of the light-emitting diode LED face the same direction (e.g., a downward direction, that is, the -z direction), but the disclosure is not limited thereto. As illustrated in FIG. 5D, the first electrode 235 and the second electrode 238 of the light-emitting diode LED may face opposite directions from each other.

The bank layer 230 may define an opening that exposes at least a part of the first electrode pad 241, and the thickness of the bank layer 230 may be substantially the same as the thickness of the light-emitting diode LED. The opening of the bank layer 230 may be filled with a filling material FM, and the second electrode pad 242 may be disposed on the upper surface of the bank layer 230 so as to be electrically connected (e.g., in contact with) the second electrode 238 of the light-emitting diode LED. The filling material FM may be an organic material having insulating properties.

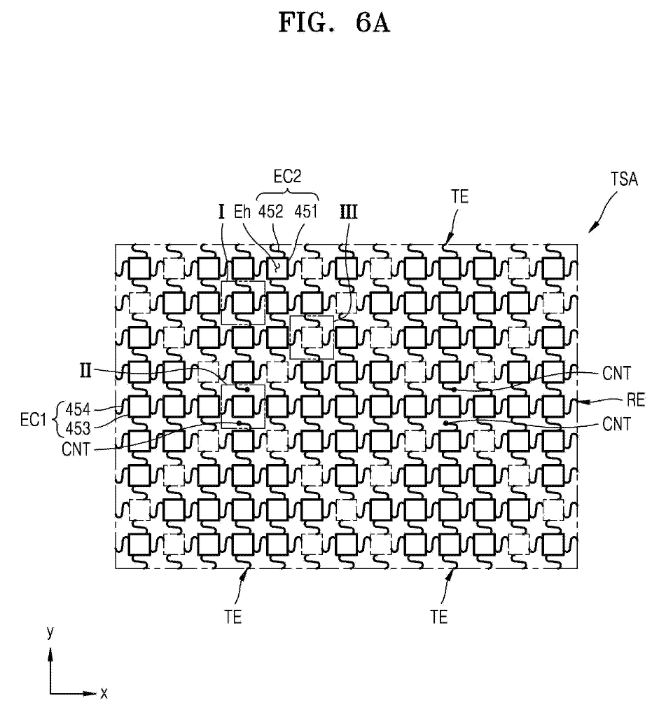

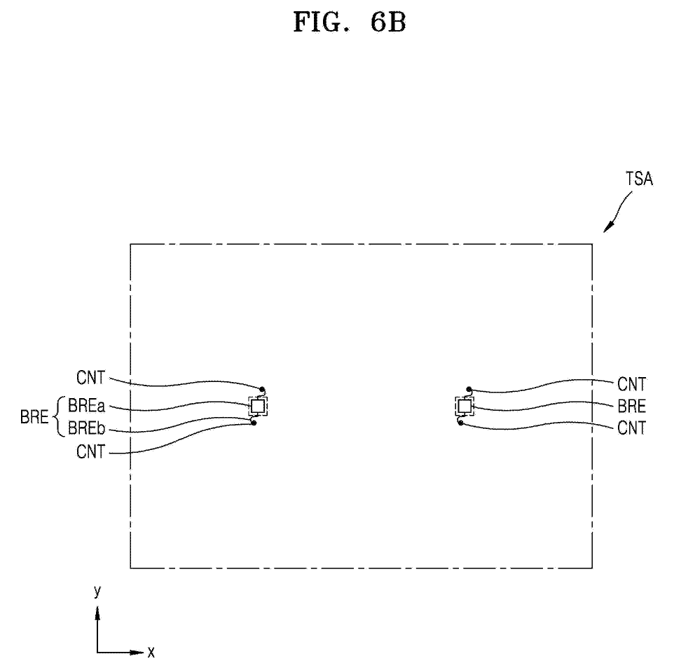

FIGS. 6A and 6B each are schematic plan views showing an embodiment of touch electrodes and connection electrodes.

Referring to FIGS. 6A and 6B, the display panel 10 (refer to FIG. 1) may include a touch sensing area TSA. First touch electrodes RE (or sensing electrodes) and second touch electrodes TE (or driving electrodes) for forming touch sensors may be provided in the touch sensing area TSA.

The first touch electrodes RE may extend in the first direction (e.g., the +x direction or the −x direction) and may be spaced apart from each other in the second direction (e.g., the +y direction or the −y direction). Each of the first touch electrodes RE may include first electrode cells EC1 arranged in the first direction (e.g., the +x direction or the −x direction). The first electrode cells EC1 neighboring each other in the first direction (e.g., the +x direction or the −x direction) may be provided integrally.

The second touch electrodes TE may extend in the second direction (e.g., the +y direction or the −y direction) to be spaced apart from each other in the first direction (e.g., the +x direction or the −x direction). Each of the second touch electrodes TE may include second electrode cells EC2 spaced apart from each other in the second direction (e.g., the +y direction or the −y direction), and connection electrodes BRE that connect the neighboring second electrode cells EC2 to each other.

In an embodiment, each of the connection electrodes BRE and each of the second electrode cells EC2 may be disposed in different conductive layers. In an embodiment, the connection electrode BRE may be included in a first electrode layer, and the second electrode cell EC2 may be included in a second electrode layer disposed on the first electrode layer, for example. At least one insulating layer may be disposed between the first electrode layer and the second electrode layer. In an embodiment, each of the first electrode cells EC1 may be disposed in the same conductive layer in which the second electrode cell EC2 is disposed.

Any one first touch electrode RE and any one second touch electrode TE may cross each other. The connection electrode BRE may be disposed in an area where the first touch electrode RE crosses the second touch electrode TE. As the first electrode cells EC1 of the first touch electrode RE are disposed in the second electrode layer and the connection electrode BRE is disposed in the first electrode layer, the first touch electrode RE and the second touch electrode TE may be electrically insulated from each other.

Each of the first electrode cells EC1 of the first touch electrode RE may include a first part 453 disposed in the first island part 11 (refer to FIG. 4A) and a second part 454 disposed in the first bridge part 12 (refer to FIG. 4A). The first parts 453 neighboring each other may be connected to each other by the second part 454. The first parts 453 and the second parts 454, which are included in the same first electrode cell EC1, may be provided integrally.

Each of the second electrode cells EC2 of the second touch electrode TE may include a first part 451 disposed in the first island part 11 and a second part 452 disposed in the first bridge part 12. The first parts 451 of the second electrode cell EC2 neighboring each other may be connected to each other by the second part 452. The first parts 451 and the second parts 452, which are included in the same second electrode cell EC2, may be provided integrally.

The first part 453 of the first electrode cell EC1 and the first part 451 of the second electrode cell EC2 may include (or define) an electrode hole Eh that exposes a central portion of the first island part 11. The electrode hole Eh (or a second opening) may overlap, in a plan view, pixels disposed in the first island part 11.

The connection electrode BRE may include a first part BREa disposed in the first island part 11 and a second part BREb disposed in the first bridge part 12. In an embodiment, the second part BREb may be disposed in the first bridge parts 12 extending in the second direction (e.g., the y direction or the −y direction). In an embodiment, the first part BREa of the connection electrode BRE may be connected to two second parts BREb, for example. The first part BREa and the second parts BREb, which are included in the same connection electrode BRE, may be provided integrally.

The first part BREa of the connection electrode BRE may include an electrode hole that exposes the central portion of the first island part 11. An electrode hole (or a first opening) may overlap, in a plan view, pixels arranged in the first island part 11. The second part BREb of the connection electrode BRE may be electrically connected to the second electrode cell EC2 through a contact hole CNT. The contact hole CNT may be defined by at least one insulating layer disposed between the second part 452 of the second electrode cell EC2 and the second part BREb of the connection electrode BRE.

In the area where the first touch electrode RE crosses the second touch electrode TE, the first touch electrode RE and the connection electrode BRE are electrically separated from each other with at least one insulating layer therebetween, and thus a kind of capacitor may be formed. When a user's finger, a stylus, etc. approaches or contacts the touch sensor, self-capacitance of each of the first touch electrode RE and the second touch electrode TE and/or mutual capacitance between the first touch electrode RE and the second touch electrode TE is changed. By detecting such a capacitance change, a touch input and a touch position of a user's finger, a stylus, etc. may be determined.

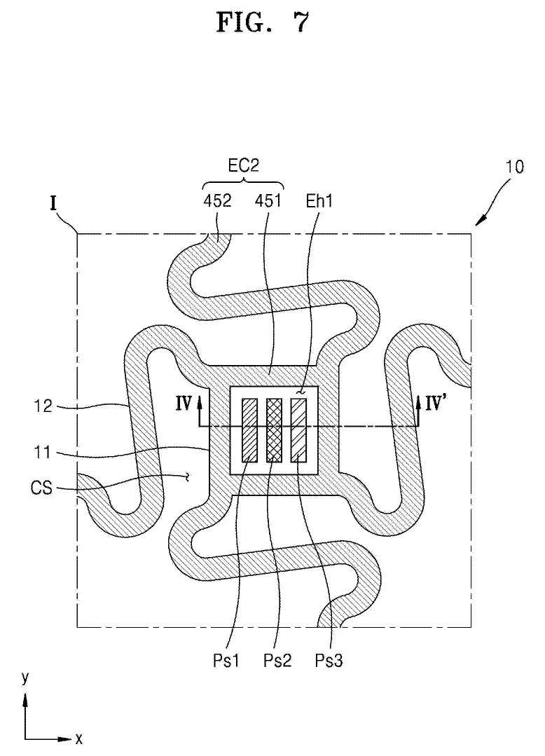

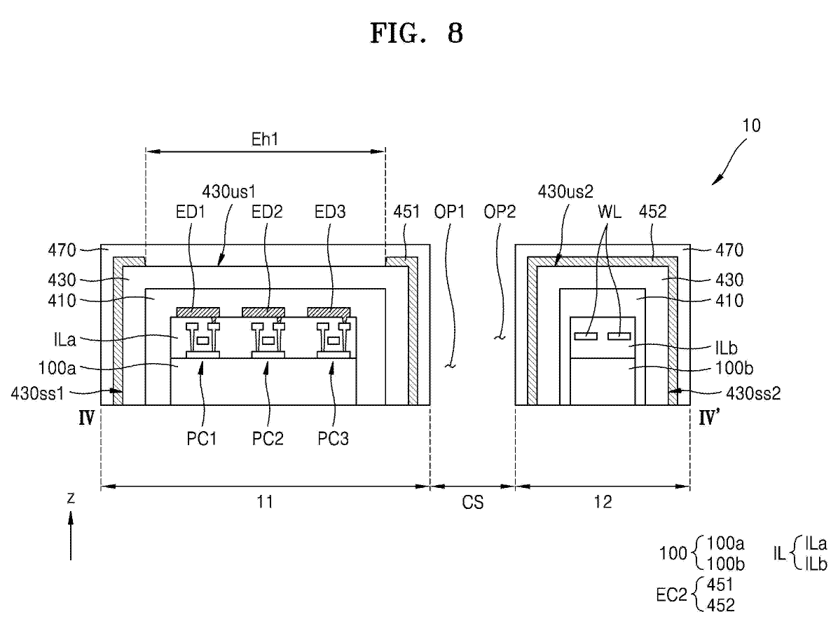

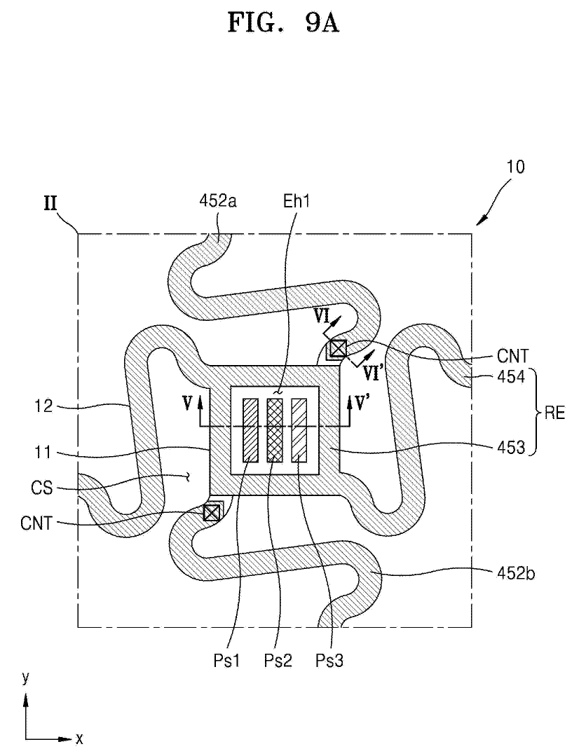

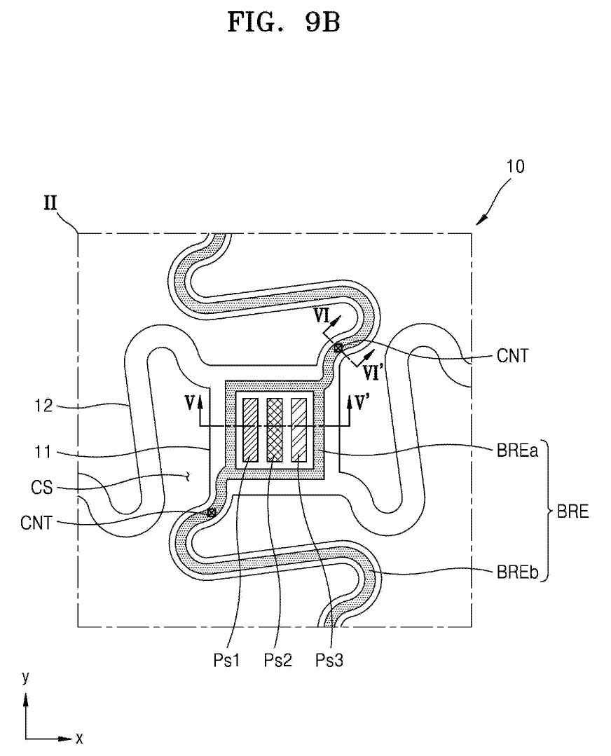

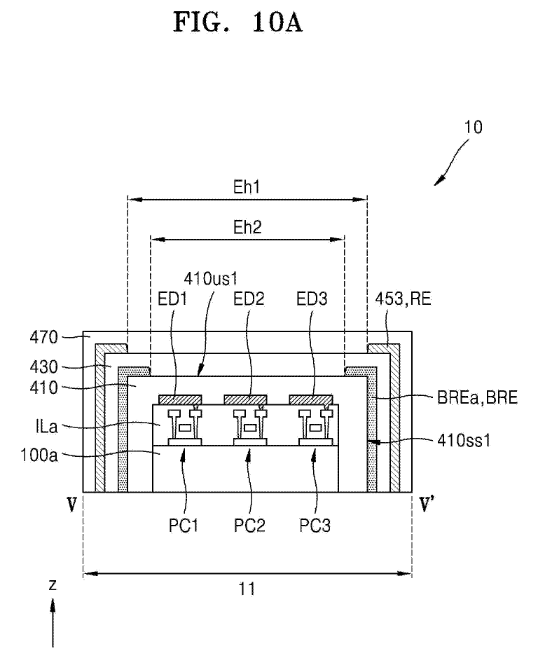

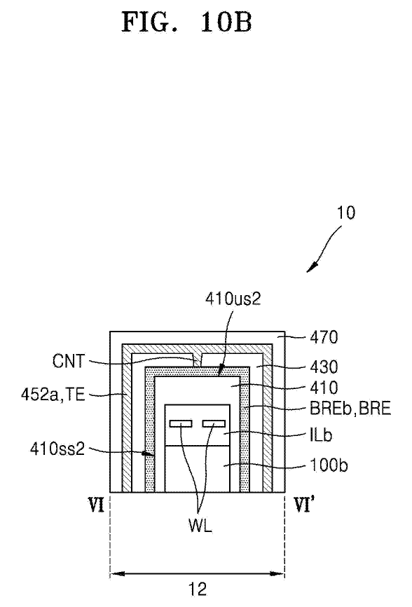

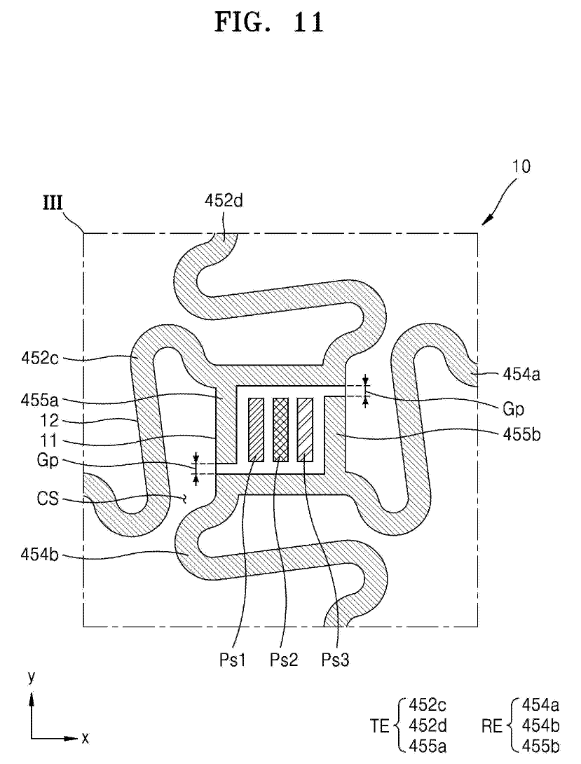

FIG. 7 is a schematic plan view showing an embodiment of a portion of a display panel. FIG. 8 is a schematic cross-sectional view of the display panel taken along line IV-IV′ of FIG. 7. FIGS. 9A and 9B each are schematic plan views showing an embodiment of a portion of a display panel. FIG. 10A is a schematic cross-sectional view of the display panel taken along line V-V′ of FIG. 9A. FIG. 10B is a schematic cross-sectional view of the display panel taken along line VI-VI′ of FIG. 9A. FIG. 11 is a schematic plan view showing an embodiment of a portion of a display panel.

FIG. 7 is an enlarged view of a region I of the display panel 10 illustrated in FIG. 6A. The region I is where the second electrode cell EC2 is disposed. FIGS. 9A and 9B each are enlarged views of a region II of the display panel 10 illustrated in FIG. 6A. The region II is where the first touch electrode RE crosses the second touch electrode TE. FIG. 11 is an enlarged view of a region III of the display panel 10 illustrated in FIG. 6A. The region III is where a boundary between the first touch electrode RE and the second touch electrode TE is disposed.

First, referring to FIGS. 7 and 8, the first island part 11 and the first bridge part 12 of the display panel 10 may be spaced apart from each other with the opening area CS therebetween. A plurality of pixels Ps1, Ps2, and Ps3 may be arranged in the first island part 11. The pixels Ps1, Ps2, and Ps3 may emit red light, green light, and blue light, respectively. FIGS. 7 and 8 illustrate that three pixels Ps1, Ps2, and Ps3 are arranged in the first island part 11, but the disclosure is not limited thereto. In another embodiment, the number of pixels arranged in the first island part 11 may be one, two, four or more. Wires WL electrically connected to first, second, and third pixel circuits PC1, PC2, and PC3 arranged next (adjacent) to each of the first island parts 11 may be arranged in the first bridge part 12. In an embodiment, a layer including the pixels Ps1, Ps2, and Ps3 and the wires WL may be also referred to as a display layer.

A substrate 100 may include an island area 100a corresponding to the first island part 11 of the display panel 10 and a bridge area 100b corresponding to the first bridge part 12 of the display panel 10. The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be a single layer including the polymer resin described above. In another embodiment, the substrate 100 may have a multilayer structure including at least one base layer including the polymer resin described above and at least one barrier layer including an inorganic insulating material. The barrier layer may be disposed, in a plan view, corresponding to the island area 100a and may be spaced apart from the bridge areas 100b. The bridge area 100b may include only the base layer and may not include the barrier layer. When the display panel 10 is stretched, the first bridge part 12 is deformed relatively much, and thus a layer including an inorganic insulating material that easily cracks may not exist in the bridge area 100b. The substrate 100 including polymer resin may be flexible, rollable, and bendable.

First, for the first island part 11, the first, second, and third pixel circuits PC1, PC2, and PC3 and the light-emitting diodes ED1, ED2, and ED3 may be arranged in the island area 100a of the substrate 100. A first pixel Ps1 may include a first light-emitting diode ED1 and the first pixel circuit PC1 electrically connected to the first light-emitting diode ED1. A second pixel Ps2 may include a second light-emitting diode ED2 and a second pixel circuit PC2 electrically connected to the second light-emitting diode ED2. A third pixel Ps3 may include a third light-emitting diode ED3 and a third pixel circuit PC3 electrically connected to the third light-emitting diode ED3.

Insulating layers may be disposed above and/or below at least one semiconductor layer and conductive layers, which constitute the pixel circuits PC1, PC2, and PC3. Insulating layers ILa arranged in the first island part 11 may include an inorganic insulating layer and/or an organic insulating layer. The light-emitting diodes ED1, ED2, and ED3 may be disposed on the insulating layers ILa. The light-emitting diodes ED1, ED2, and ED3 may emit light of different colors or light of the same color. The boundary of each of the pixels Ps1, Ps2, and Ps3 illustrated in FIG. 7 denotes the boundary of an emission area of each of the light-emitting diodes ED1, ED2, and ED3.

A first organic layer 410 may be disposed on the light-emitting diodes ED1, ED2, and ED3. The first organic layer 410 may cover the light-emitting diodes ED1, ED2, and ED3, and may extend to cover the side surfaces of the insulating layers ILa and the side surface of the island area 100a of the substrate 100. The first organic layer 410 may include an organic insulating material. In an embodiment, the first organic layer 410 may include an organic material such as resin. In some embodiments, the first organic layer 410 may include urethane, epoxy, and/or acrylate. The first organic layer 410 may include a photosensitive material, e.g., a material such as photoresist.

A second organic layer 430 may be disposed on the first organic layer 410. A first electrode layer may be disposed between the first organic layer 410 and the second organic layer 430. The second organic layer 430 may extend to cover the upper surface and the side surface of the first organic layer 410. The second organic layer 430 may include an organic insulating material. In an embodiment, the second organic layer 430 may include an organic material such as resin. In some embodiments, the second organic layer 430 may include urethane, epoxy, and/or acrylate. The second organic layer 430 may include a photosensitive material, e.g., a material such as photoresist.

For the first bridge part 12, the wires WL may be arranged in the bridge area 100b of the substrate 100. The wires WL may be a signal line (e.g., a gate line, a data line, etc.) for supplying electrical signals to transistors included in the pixel circuits PC1, PC2, and PC3 or a voltage line (e.g., a power voltage line, an initialization voltage line, etc.) for supplying a voltage.

Insulating layers may be disposed above and/or below at least one conductive layer including the wires WL. Insulating layers ILb arranged in the first bridge part 12 may include an organic insulating layer. In an embodiment, of the insulating layers ILa, the inorganic insulating layers arranged in the first island part 11 may have an isolated shape corresponding to the first island part 11 in a plan view, for example. The inorganic insulating layers may be spaced apart from the first bridge part 12 and may not overlap with the first bridge part 12.

The first organic layer 410 may be disposed on the insulating layers ILb. The first organic layer 410 may extend to cover the upper surfaces and the side surfaces of the insulating layers ILb. The first organic layer 410 of the first island part 11 and the first organic layer 410 of the first bridge part 12 may be simultaneously formed through the same process, and may include the same material as each other. In an embodiment, an opening OP1 defined in the substrate 100 and an opening OP2 defined in an insulating layer IL are arranged to overlap each other, and the first organic layer 410 may cover the side walls of the openings OP1 and OP2, for example.

The second organic layer 430 may be disposed on the first organic layer 410. The second organic layer 430 may extend to cover the upper surface and the side surface of the first organic layer 410. The second organic layer 430 of the first island part 11 and the second organic layer 430 of the first bridge part 12 may be simultaneously formed through the same process, and may include the same material as each other.

A second electrode layer may be disposed on the second organic layers 430 of the first island part 11 and the first bridge part 12. The second electrode layer may include the first electrode cell EC1 (refer to FIG. 6A) of the first touch electrode RE (refer to FIG. 6A) and the second electrode cell EC2 of the second touch electrode TE (refer to FIG. 6A). The first electrode cell EC1 may have a structure that is the same as or similar to the second electrode cell EC2 illustrated in FIG. 8. The second electrode layer may include a conductive material including molybdenum (Mo), aluminum (Al), copper (Cu), titanium (Ti), or the like, and may be formed in a multilayer or a single layer including the material described above.

The second electrode cell EC2 may include the first part 451 extending along an edge of the island area 100a of the substrate 100 and the second part 452 extending along an edge of the bridge area 100b. The second organic layer 430 has a first side surface 430ss1 that is approximately parallel to the side surface of the first island part 11 (or the side surface of the island area 100a) and a first upper surface 430us1 that overlaps the upper surface of the first island part 11 (or the upper surface of the island area 100a). The second organic layer 430 has a second side surface 430ss2 that is approximately parallel to the side surface of the first bridge part 12 (or the side surface of the bridge area 100b) and a second upper surface 430us2 that overlaps the upper surface of the first bridge part 12 (or the upper surface of the bridge area 100b).

The first part 451 of the second electrode cell EC2 extending along the edge of the island area 100a in a plan view may mean that the first part 451 is disposed to cover an outer portion of the first upper surface 430us1 and the first side surface 430ss1 of the second organic layer 430. The first part 451 may have a first electrode hole Eh1 (or the first opening) that overlaps the pixels Ps1, Ps2, and Ps3 in a plan view.

Likewise, the second part 452 of the second electrode cell EC2 extending along the bridge area 100b in a plan view may mean that the second part 452 is disposed to cover the second upper surface 430us2 and the second side surface 430ss2 of the second organic layer 430. In an embodiment, the second part 452 may cover an entirety of the second upper surface 430us2 of the second organic layer 430. As the second electrode cell EC2 extends to the first side surface 430ss1 and the second side surface 430ss2 of the second organic layer 430, the second electrode cell EC2 may secure a sufficient width to have a relatively low resistance.

A protection layer 470 may be disposed on the second electrode layer. The protection layer 470 may include an organic insulating material. In an embodiment, the protection layer 470 may include an organic material such as resin. In some embodiments, the protection layer 470 may include urethane, epoxy, and/or acrylate. The protection layer 470 may include a photosensitive material, e.g., a material such as photoresist.

Referring to FIGS. 9A, 9B, 10A, and 10B, the first touch electrode RE may include the first electrode cell EC1 (refer to FIG. 6A), and the first electrode cell EC1 may include the first part 453 extending along the edge of the island area 100a of the substrate 100 and the second part 454 extending along the edge of the bridge area 100b. In other words, in the area where the first touch electrode RE crosses the second touch electrode TE, the first part 453 of the first electrode cell EC1 may be disposed to cover the outer portion of the first upper surface 430us1 and the first side surface 430ss1 of the second organic layer 430. The first part 453 of the first electrode cell EC1 may have the first electrode hole Eh1 overlapping the pixels Ps1, Ps2, and Ps3 in a plan view.

In the area where the first touch electrode RE crosses the second touch electrode TE, the second part 454 of the first electrode cell EC1 may be disposed in the first bridge parts 12 that connect the neighboring first island parts 11 in the first direction (e.g., the +x direction or the −x direction). The second part 454 of the first electrode cell EC1 may be disposed to cover the second upper surface 430us2 and the second side surface 430ss2 of the second organic layer 430. The first part 453 and the second parts 454 of the first electrode cell EC1 may be provided integrally.

The second touch electrode TE may include a second-1 part 452a and a second-2 part 452b. The second-1 part 452a may be included in a second-1 electrode cell disposed in the +y direction, and the second-2 part 452b may be included in a second-2 electrode cell disposed in the −y direction. The second-1 part 452a and the second-2 part 452b may be spaced apart from the first part 453 of the first touch electrode RE, and may be electrically separated from the second-1 electrode cell, the second-2 electrode cell, and the first touch electrode RE.

The connection electrode BRE may include the first part BREa extending along the edge of the island area 100a of the substrate 100 and the second part BREb extending along the edge of the bridge area 100b. The first organic layer 410 has a first side surface 410ss1 that is approximately parallel to the side surface of the first island part 11 (or the side surface of the island area 100a) and a first upper surface 410us1 that overlaps the upper surface of the first island part 11 (or the upper surface of the island area 100a). The first organic layer 410 has a second side surface 410ss2 that is approximately parallel to the side surface of the first bridge part 12 (or the side surface of the bridge area 100b) and a second upper surface 410us2 that overlaps the upper surface of the first bridge part 12 (or the upper surface of the bridge area 100b).

In the area where the first touch electrode RE crosses the second touch electrode TE, the first part BREa of the connection electrode BRE may be disposed to cover an outer portion of the first upper surface 410us1 of the first organic layer 410 and the first side surface 410ss1 of the first organic layer 410. The first part BREa of the connection electrode BRE may have a second electrode hole Eh2 (or the second opening) that overlaps the pixels Ps1, Ps2, and Ps3 in a plan view.

The second part BREb of the connection electrode BRE may be disposed in the first bridge parts 12 that connect the neighboring first island parts 11 in the second direction (e.g., the y direction or the −y direction). The second part BREb of the connection electrode BRE may be disposed to cover the second side surface 410ss2 and the second upper surface 410us2 of the first organic layer 410.

The first part BREa of the connection electrode BRE and the first part 453 of the first touch electrode RE may be electrically separated from each other by the second organic layer 430. The second-1 part 452a of the second-1 electrode cell may be electrically connected to the second part BREb of the connection electrode BRE through the contact hole CNT that penetrates the second organic layer 430. Likewise, the second-2 part 452b of the second-2 electrode cell may be electrically connected to the second part BREb of the connection electrode BRE through the contact hole CNT that penetrates the second organic layer 430. Accordingly, the second-1 electrode cell and the second-2 electrode cell are electrically connected to each other through the connection electrode BRE, and may form the second touch electrode TE extending in in the second direction (e.g., the y direction or the −y direction).

Referring to FIG. 11, in an area where the boundary between the first touch electrode RE and the second touch electrode TE is disposed, the first touch electrode RE and the second touch electrode TE may be spaced apart from each other to be electrically separated from each other.

The second touch electrode TE may include a first dummy part 455a disposed in the first island part 11, and a second-3 part 452c and a second-4 part 452d connected to the first dummy part 455a and arranged in the first bridge part 12. The first dummy part 455a of the second touch electrode TE may extend along a portion of the edge of the island area 100a of the substrate 100. In other words, the first dummy part 455a of the second touch electrode TE may be disposed to cover a portion of the outer portion of the first upper surface 430us1 of the second organic layer 430 and a portion of the side surface of the first side surface 430ss1. The second-3 part 452c and the second-4 part 452d of the second touch electrode TE may each be arranged to cover the second upper surface 430us2 and the second side surface 430ss2 of the second organic layer 430 corresponding to the first bridge part 12.

The first touch electrode RE may include a second dummy part 455b disposed in the first island part 11, and a second-5 part 454a and a second-6 part 454b connected to the second dummy part 455b and arranged in the first bridge part 12. The second dummy part 455b of the first touch electrode RE may extend along a portion of the edge of the island area 100a of the substrate 100. The second dummy part 455b of the first touch electrode RE may be disposed to cover a remaining (the other) portion of the outer portion of the first upper surface 430us1 of the second organic layer 430 and a remaining (the other) portion of the first side surface 430ss1. The second-5 part 454a and the second-6 part 454b of the first touch electrode RE may each be arranged to cover the second upper surface 430us2 and the second side surface 430ss2 of the second organic layer 430 corresponding to first bridge part 12.

The first dummy part 455a and the second dummy part 455b may be spaced apart from each other with a gap Gp therebetween. Accordingly, the first touch electrode RE and the second touch electrode TE may be electrically separated from each other. FIG. 11 illustrates, in an embodiment, the boundary of the first touch electrode RE disposed on the lower right side and the second touch electrode TE disposed on the upper left side. The number of dummy parts arranged in one first island part 11 may be two or more depending on the number of the second touch electrodes TE and the number of the first touch electrodes RE meet in the first island part 11. In another embodiment, the dummy part of the first touch electrode RE and the dummy part of the second touch electrode TE may be omitted.

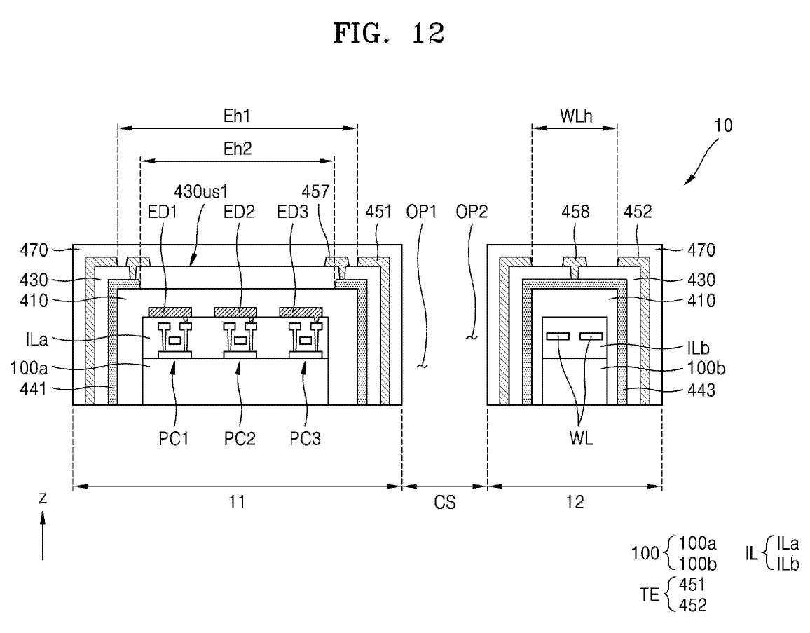

FIG. 12 is a schematic cross-sectional view showing an embodiment of a portion of a display panel. FIG. 12 is similar to FIG. 8, but differs in that the second electrode layer further includes an auxiliary electrode 457 and a first auxiliary wire 458. Hereinafter, descriptions of identical or similar configurations are omitted, and differences are mainly explained.

Referring to FIG. 12, the first island part 11 and the first bridge part 12 of the display panel 10 may be spaced apart from each other with the opening area CS therebetween. The pixels Ps1, Ps2, and Ps3 may be arranged in the first island part 11. The wires WL electrically connected to the pixel circuits PC1, PC2, and PC3 disposed next (adjacent) to each of the first island parts 11 may be arranged in the first bridge part 12.

The substrate 100 may include the island area 100a corresponding to the first island part 11 of the display panel 10 and the bridge area 100b corresponding to the first bridge part 12 of the display panel 10.

For the first island part 11, the pixel circuits PC1, PC2, and PC3 and the light-emitting diodes ED1, ED2, and ED3 may be arranged in the island area 100a of the substrate 100. The insulating layers ILa may be disposed above and/or below at least one semiconductor layer and conductive layers, which constitute the pixel circuits PC1, PC2, and PC3.

The first organic layer 410 may be disposed on the light-emitting diodes ED1, ED2, and ED3. The first organic layer 410 may cover the light-emitting diodes ED1, ED2, and ED3, and may extend to cover the side surfaces of the insulating layers ILa and the side surface of the island area 100a of the substrate 100.

The first electrode layer may be disposed on the first organic layer 410. The first electrode layer may include the connection electrode BRE (refer to FIG. 6B) and a second auxiliary wire. The second auxiliary wire may include a second-1 auxiliary wire 441 and a second-2 auxiliary wire 443. The second auxiliary wires may be spaced apart from the connection electrodes BRE in a plan view.

The second-1 auxiliary wire 441 may extend along the edge of the island area 100a in a plan view. In other words, the second-1 auxiliary wire 441 may be disposed to cover an outer portion of the upper surface and the side surface of the first organic layer 410 of the first island part 11. The second-1 auxiliary wire 441 may have the second electrode hole Eh2 overlapping the pixels Ps1, Ps2, and Ps3 in a plan view. The second-2 auxiliary wire 443 may extend along the edge of the bridge area 100b in a plan view. The second-2 auxiliary wire 443 may be disposed to cover the upper surface and the side surface of the first organic layer 410 of the first bridge part 12. The second-1 auxiliary wire 441 and the second-2 auxiliary wire 443 may be provided integrally.

The second organic layer 430 may be disposed on the first electrode layer. The second electrode layer may be disposed on the second organic layer 430. The second electrode layer may include the first touch electrode RE (refer to FIG. 6A), the second electrode cell EC2 (refer to FIG. 6A) of the second touch electrode TE (refer to FIG. 6A), the auxiliary electrode 457, and the first auxiliary wire 458.

The second touch electrode TE may include the first part 451 extending along the edge of the island area 100a of the substrate 100 and the second part 452 extending along the edge of the bridge area 100b. The first part 451 of the second touch electrode TE may be disposed to cover an outer portion of the upper surface and the side surface of the second organic layer 430 in the first island part 11. The first part 451 of the second touch electrode TE may have the first electrode hole Eh1 overlapping the pixels Ps1, Ps2, and Ps3 in a plan view.

The second part 452 of the second touch electrode TE may be disposed to cover the outer portion of the upper surface and the side surface of the second organic layer 430 in the first bridge part 12. The second part 452 of the second touch electrode TE may have a wire opening WLh (or a third opening) that exposes the upper surface of the second organic layer 430. The wire opening WLh may extend in an extension direction of the first bridge part 12.

The auxiliary electrode 457 may be disposed within the first electrode hole Eh1 in a plan view. The auxiliary electrode 457 may be surrounded by the first part 451 in a plan view, and may be spaced apart from the first part 451 so as to have an isolated shape. The auxiliary electrode 457 may be electrically connected to the second-1 auxiliary wire 441 through a contact hole that penetrates the second organic layer 430.

The first auxiliary wire 458 may be disposed within the wire opening WLh in a plan view. The first auxiliary wire 458 may be electrically connected to the second-2 auxiliary wire 443 through the contact hole that penetrates the second organic layer 430.

The protection layer 470 may be disposed on the second electrode layer. The protection layer 470 may extend to cover the upper surface and the side surface of the first part 451.

In an embodiment, the auxiliary electrode 457, the first auxiliary wire 458, and the second auxiliary wire may be parts of a sensor module. In an embodiment, the auxiliary electrode 457, the first auxiliary wire 458, and the second auxiliary wire may be parts of a stretch sensor for sensing stretching of the display panel 10, an input sensor, or a fingerprint sensor, for example. The disclosure is not limited thereto, and the auxiliary electrode 457, the first auxiliary wire 458, and the second auxiliary wire may be used as signal lines or voltage lines.

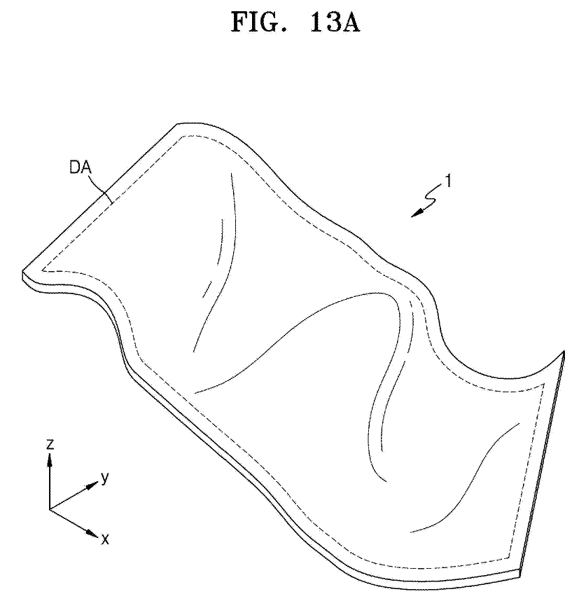

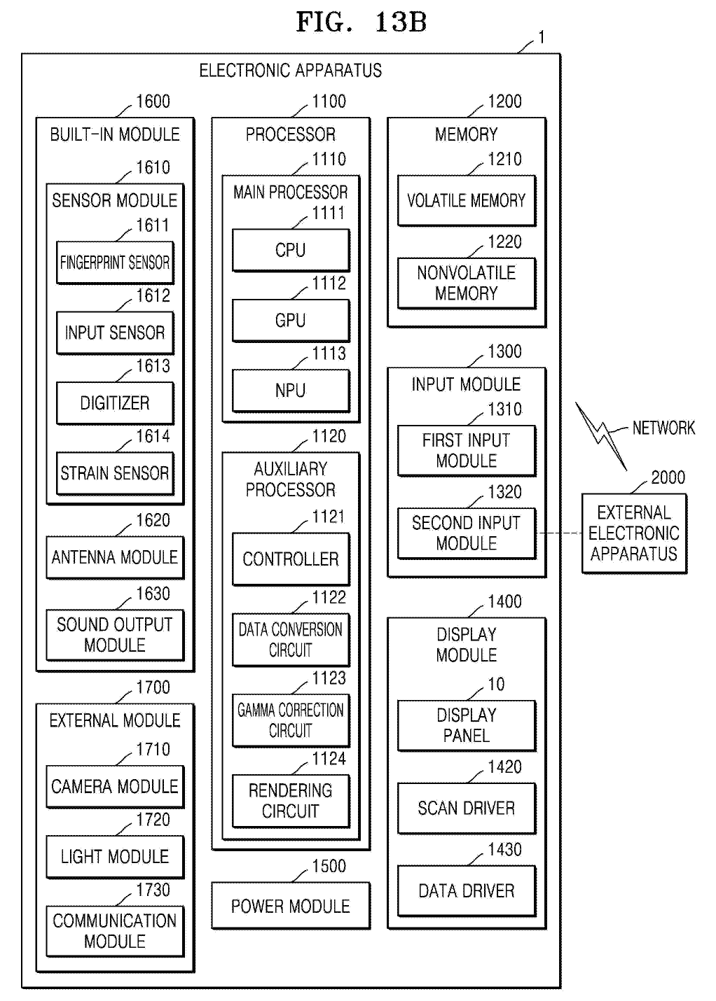

FIG. 13A is a schematic perspective view showing an embodiment of an electronic device 1 including a display panel.

FIG. 13B is a block diagram showing an embodiment of the electronic device 1 including a display panel 10.

Referring to FIG. 13A, the electronic device 1 may be freely deformed in three dimensions, and may provide a three-dimensional image surface through the display area DA. The electronic device 1 being freely deformed in three dimensions may be distinguished from the operation of an electronic device having a rollable display device, in which, while a part of the display area that is rolled up is being viewed by a user, another part of the display area that has been rolled up is unrolled so that the entirety of the display area is viewed by the user (or while the entirety of the display area that is unrolled is being viewed by a user, the display area is rolled up so that only a part of the display area is viewed by the user). By the embodiments described above, while the electronic device 1 is deformed in the x direction, the y direction, and/or the z direction, the electronic device 1 may be deformed such that the area of the entirety of the display area DA increases or decreases.

Referring to FIG. 13B, the electronic device 1 may include a processor 1100, a memory 1200, an input module 1300, a display module 1400, a power module 1500, an internal module 1600, and an external module 1700. In an embodiment, in the electronic device 1, at least one of the elements described above may be omitted, or one or more other elements may be added. In an embodiment, some elements (e.g., the internal module 1600) among the elements described above may be integrated into another element (e.g., the display module 1400).

The processor 1100 may execute software to control at least one other element (e.g., a hardware or software element) of the electronic device 1 connected to the processor 1100 and perform a variety of data processing or operations. In an embodiment, as at least a part of data processing or operation, the processor 1100 may store, in a volatile memory 1210, commands or data received from another element (e.g., the input module 1300, a sensor module 1610, or a communication module 1730), process the commands or data stored in the volatile memory 1210, and store resulting data in a non-volatile memory 1220.

The processor 1100 may include a main processor 1110 and an auxiliary processor 1120. The main processor 1110 may include at least one of a central processing unit (“CPU”) 1111 or an application processor (“AP”). The main processor 1110 may further include at least one of a graphics processing unit (“GPU”) 1112, a communication processor (“CP”), and an image signal processor (“ISP”). The main processor 1110 may further include a neural processing unit (“NPU”) 1113. The NPU is a processor specialized for processing an artificial intelligence model, and the artificial intelligence model may be generated through machine learning. The artificial intelligence model may include a plurality of artificial neural network layers. The artificial neural network may be one of a deep neural network (“DNN”), a convolutional neural network (“CNN”), a recurrent neural network (“RNN”), a restricted Boltzmann machine (“RBM”), a deep belief network (“DBN”), a bidirectional recurrent deep neural network (“BRDNN”), deep Q-networks, or a combination of at least two of the networks described above. The artificial intelligence model may include a software structure in addition to or as an alternative to the hardware structure. At least one of the processing unit and the processor described above may be implemented as a single integrated configuration (e.g., a single chip), or each of the two may be implemented as an independent configuration (e.g., a plurality of chips).

The auxiliary processor 1120 may include a controller 1121. The controller 1121 may include an interface conversion circuit and a timing control circuit. The controller 1121 may receive an image signal from the main processor 1110, convert a data format of the image signal to fit the interface specifications with the display module 1400, and output the image data. The controller 1121 may output various control signals for driving the display module 1400.

The auxiliary processor 1120 may further include a data processing circuit, such as a data conversion circuit 1122, a gamma correction circuit 1123, or a rendering circuit 1124. The data conversion circuit 1122 may receive image data from the controller 1121, compensate for the image data so that an image is displayed at a desired luminance according to characteristics of the electronic device 1 or user settings, or convert the image data to reduce power consumption or compensate for afterimages. The gamma correction circuit 1123 may convert image data or a gamma reference voltage so that an image displayed on the electronic device 1 has desired gamma characteristics. The rendering circuit 1124 may receive the image data from the controller 1121 and render the image data by considering the pixel layout of the display panel 10 applied to the electronic device 1. At least one of the data conversion circuit 1122, the gamma correction circuit 1123, or the rendering circuit 1124 may be integrated into another element (e.g., the main processor 1110 or the controller 1121). In an embodiment, the auxiliary processor 1120 may be integrated into a data driver 1430.

The memory 1200 may store various pieces of data which are used by at least one element (e.g., the processor 1100 or the sensor module 1610) of the electronic device 1, and input data or output data regarding commands related to the various pieces of data. The memory 1200 may include at least one of the volatile memory 1210 or the non-volatile memory 1220.

The input module 1300 may receive, from the outside (e.g., a user or an external electronic device 2000)) of the electronic device 1, commands or data for use in an element (e.g., the processor 1100, the sensor module 1610, or an audio output module 1630) of the electronic device 1.

The input module 1300 may include a first input module 1310 which receives commands or data from a user, and a second input module 1320 which receives commands or data from the external electronic device 2000.

The first input module 1310 may include a microphone, a mouse, a keyboard, or a pen (e.g., a passive pen or an active pen). The first input module 1310 may include a mechanical input means, such as a button disposed on a rear surface or side surface of the electronic device 1, a dome switch, a jog wheel, or a jog switch, or a touch input means. The touch input means may include an input detection layer of the display panel 10.

The second input module 1320 may be connect, by wire or wirelessly, to the various types of external electronic devices 2000 connected to the electronic device 1. In an embodiment, the second input module 1320 may include a high definition multimedia interface (“HDMI”), a universal serial bus (“USB”) interface, a secure digital (“SD”) card interface, or an audio interface. The second input module 1320 may include a connector for physically connecting the electronic device 1 to the external electronic device 2000, e.g., an HDMI connector, a USB connector, an SD card connector, or an audio connector (e.g., a headphone connector). In response to the external electronic device 2000 being connected to the second input module 1320, the electronic device 1 may perform an appropriate control related to the connected external electronic device 2000.

The display module 1400 ma provide information visually to a user. The display module 1400 may include the display panel 10, a scan driver 1420, and the data driver 1430.

The display panel 10 may display (output) information processed in the electronic device 1. The display panel 10 may display execution screen information on an application running on the electronic device 1, or user interface (“UI”) or graphic user interface (“GUI”) information according to the execution screen information.

The scan driver 1420 may be disposed (e.g., mounted), as a driving chip, in the display panel 10. In an alternative embodiment, the scan driver 1420 may be formed directly on the display panel 10. In an embodiment, the scan driver 1420 may include an amorphous silicon TFT gate driver circuit (“ASG”), a low temperature polycrystalline silicon (“LTPS”) TFT gate driver circuit, or an oxide semiconductor TFT gate driver circuit (“OSG”), which is embedded in the display panel 10, for example. The scan driver 1420 may receive a control signal from the controller 1121, and output scan signals to the display panel 10 in response to the control signal.

The display panel 10 may further include an emission control driver. The emission control driver may output an emission control signal to the display panel 10 in response to the control signal received from the controller 1121. The emission control driver may be formed distinguished from the scan driver 1420, or may be integrated into the scan driver 1420.

The data driver 1430 may receive a control signal from the controller 1121, convert image data into a data voltage in an analog voltage form in response to the control signal, and then output data voltages to the display panel 10.

The data driver 1430 may be integrated into some configurations of the auxiliary processor 1120. In an embodiment, the data driver 1430 may be provided as a timing controller embedded driver integrated circuit (“IC”) which includes the controller 1121, for example.

The power module 1500 may supply power to elements of the electronic device 1. The power module 1500 may include a battery which charges a power voltage. In addition, the power module 1500 may include a connection port, and the connection port may be included in the second input module 1320 to which an external charger for supplying power to charge the battery is connected. In an alternative embodiment, the power module 1500 may include a wireless power transmission/reception member so as to charge the battery in a wireless manner. The wireless power transmission/reception member may include a plurality of coil-shaped antenna radiators. The power module 1500 may include a power management integrated circuit (“PMIC”). The PMIC may supply optimized power to each of elements of the electronic device 1.

The electronic device 1 may further include the internal module 1600 and the external module 1700. The internal module 1600 may include the sensor module 1610, an antenna module 1620, and the audio output module 1630. The external module 1700 may include a camera module 1710, a light module 1720, and/or the communication module 1730.

The sensor module 1610 may include a touch sensor driving unit and touch electrodes of the input detection layer of the display panel 10. The sensor module 1610 may detect an input by a user's body or an input by a pen, and generate an electric signal or data value corresponding to the input. The sensor module 1610 may include at least one of a fingerprint sensor 1611, an input sensor 1612, a digitizer 1613, and a strain sensor 1614.

The fingerprint sensor 1611 may generate a data value corresponding to user's fingerprint. The fingerprint sensor 1611 may include any one of an optical fingerprint sensor or a capacitive fingerprint sensor.

The input sensor 1612 may generate a data value corresponding to coordinate information of an input by a user's body or an input by a pen. The input sensor 1612 may generate a data value based on a change in electrostatic capacitance due to an input. The input sensor 1612 may detect an input by a passive pen or transmit/receive data to/from an active pen.

The input sensor 1612 may measure biometric signals, such as blood pressure, water, or body fat. In an embodiment, when a user touches a part of the body to a sensor layer or a sensing panel and does not move for a predetermined period of time, the input sensor 1612 may detect a biometric signal based on a change in an electric field caused by the body part and output information desired by the user to the display module 1400, for example.

The digitizer 1613 may generate a data value corresponding to coordinate information of an input by a pen. The digitizer 1613 may generate a data value based on an electromagnetic change caused by the input. The digitizer 1613 may detect an input by a passive pen or transmit/receive data to/from an active pen.

The strain sensor 1614 may include layers, patterns, or wires, in which measurable physical quantity changes according to the elongation of the display panel 10. In an embodiment, the strain sensor 1614 may include wires with resistance and/or capacitance that changes due to the stretch of the display panel 10, for example. In another embodiment, the strain sensor 1614 may include an optical layer or an optical pattern, in which transmittance and/or reflectivity changes due to the elongation of the display panel 10.

Based on the physical quantity according to the elongation of the display panel 10 measured by the strain sensor 1614, the electronic device 1 may improve the image quality of an image implemented in the display panel 10 or control the display module 1400. The control operation of the display module 1400 may include an operation of displaying an operation image for protecting the display panel 10, cutting off a voltage for driving the display panel 10, or stopping an extension operation of the display panel 10, for example.

In an embodiment, at least one of the fingerprint sensor 1611, the input sensor 1612, or the digitizer 1613 may be embedded in the display panel 10. In an embodiment, at least one of the fingerprint sensor 1611, the input sensor 1612, or the digitizer 1613 may be formed through a process which is continuous with a process of forming pixel circuits and light-emitting diodes of the display panel 10, for example. Due to the above, the display panel 10 may function as one of the input modules 1300 which provide an input interface between the electronic device 1 and the user, while also functioning as the display module 1400 which provides an output interface between the electronic device 1 and the user.

In an embodiment, at least two of the fingerprint sensor 1611, the input sensor 1612, or the digitizer 1613 may be integrated into one sensing panel through a same process. The sensing panel may be disposed between the display panel 10 and a window which is disposed in an upper portion of the display panel 10, but the disclosure is not limited thereto.

The antenna module 1620 may include one or more antennas for transmitting signals or power to the outside or receiving signals or power from the outside. In an embodiment, the communication module 1730 may transmit signals to an external electronic device or receive signals from the external electronic device through an antenna suitable for a communication scheme. An antenna pattern of the antenna module 1620 may be integrated into a configuration (e.g., the display panel 10) of the display module 1400 or the input sensor 1612.

The audio output module 1630, which is a device for outputting audio signals to the outside of the electronic device 1, may output audio data which is received from the communication module 1730 or stored in the memory 1200 in a call signal reception mode, a call mode or recording mode, a speech recognition mode, or a broadcast reception mode. The audio output module 1630 may output an audio signal related to a function performed in the electronic device 1 (e.g., call signal reception sound, message reception sound, etc.). The audio output module 1630 may include a receiver and a speaker. At least one of the receiver or the speaker may be an audio generation device which is attached to a lower portion of the display panel 10 to vibrate the display panel 10 and output sound. The audio generation device may be a piezoelectric element or piezoelectric actuator which contracts and expands in response to an electric signal, or an exciter which generates a magnetic force by a voice coil and vibrates the display panel 10.

The camera module 1710 may capture still images and moving images. In an embodiment, the camera module 1710 may include one or more lenses, an image sensor, or an image signal processor. The camera module 1710 may further include an infrared camera which is capable of measuring the presence or absence of a user, a user's position, a user's gaze, or the like.

The light module 1720 may output a signal to notify the occurrence of an event by light from a light source, or provide light for image acquisition. Here, embodiments of the event occurrence may include receiving a message, receiving a call signal, missing a call, an alarm, a schedule reminder, receiving an e-mail, or notifying battery charge capacity information. The light module 1720 may include a light-emitting diode or a xenon lamp. The light module 1720 may emit light of one or more colors to a front surface or rear surface of the electronic device 1. The light module 1720 may be operate in conjunction with or independently of the camera module 1710.

The communication module 1730 may support establishment of a wired or wireless communication channel between the electronic device 1 and the external electronic device 2000, and performing of a communication through the established communication channel. The communication module 1730 may include any one or all of a wireless communication module, such as a cellular communication module, a short-range wireless communication module, or a global navigation satellite system (“GNSS”) communication module, a local area network (“LAN”) communication module, or a wired communication module, such as a power line communication module. The communication module 1730 may transmit/receive wireless signals on the Internet by at least one of wireless LAN (“WLAN”), wireless-fidelity (“Wi-Fi”), Wi-Fi direct, or digital living network alliance (“DLNA”) technologies. In addition, the communication module 1730 may support short-range communication by at least one of Bluetooth^{TM}, radio frequency identification (“RFID”), infrared data association (“IrDA”), ultra-wideband (“UWB”), ZigBee, near field communication (“NFC”), Wi-Fi, Wi-Fi direct, or wireless USB technologies. The communication modules 1730 of various types described above may be implemented as one chip or as separate chips.

The electronic device 1, which is freely deformed in three dimensions, may provide a three-dimensionally deformable image surface. In another embodiment, the electronic device 1 may include an image providing area having a fixed shape, and in a process of manufacturing an electronic device, the display panel 10 is disposed in the image providing area of the electronic device 1 described above, and the display panel 10 in a three-dimensionally deformed state may be fixed to the electronic device 1.

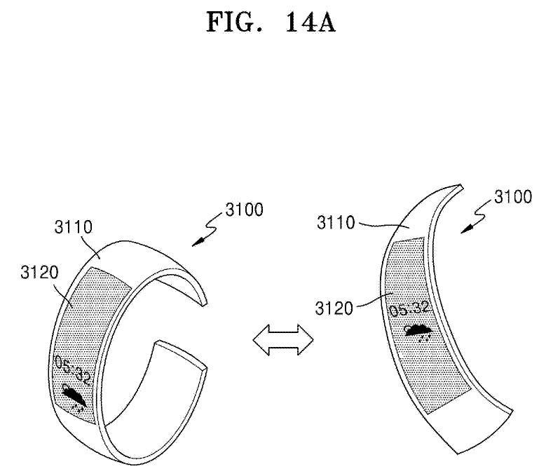

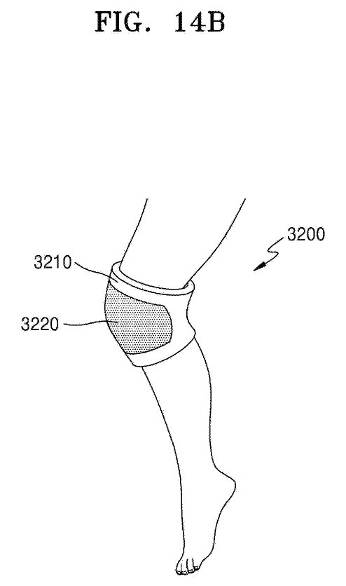

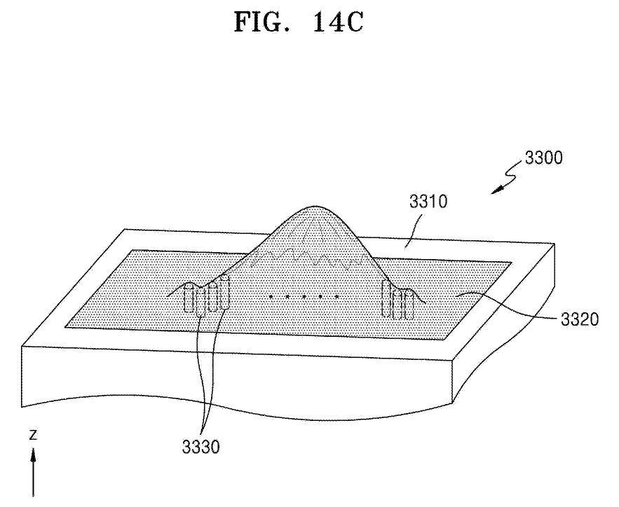

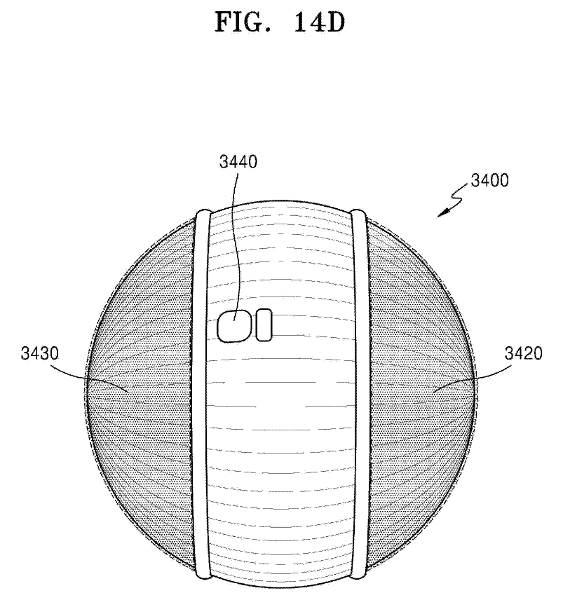

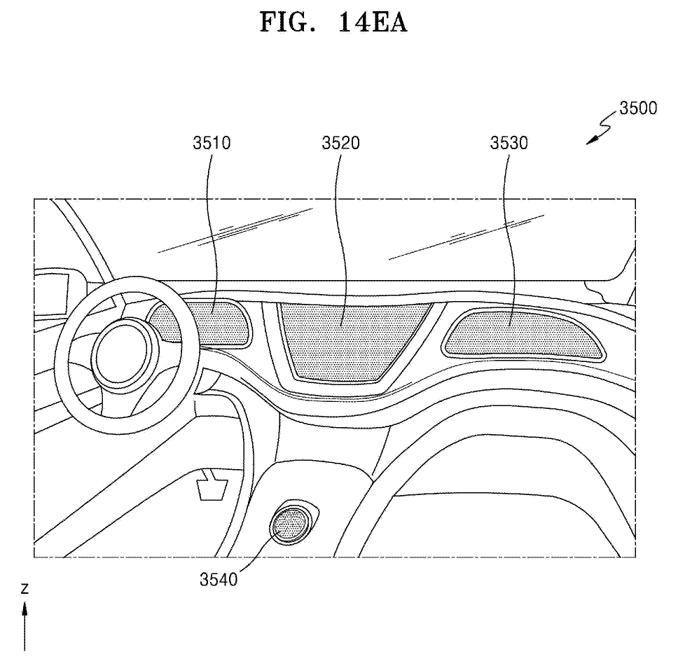

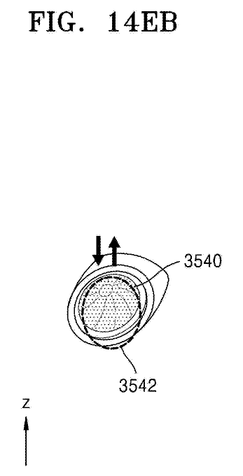

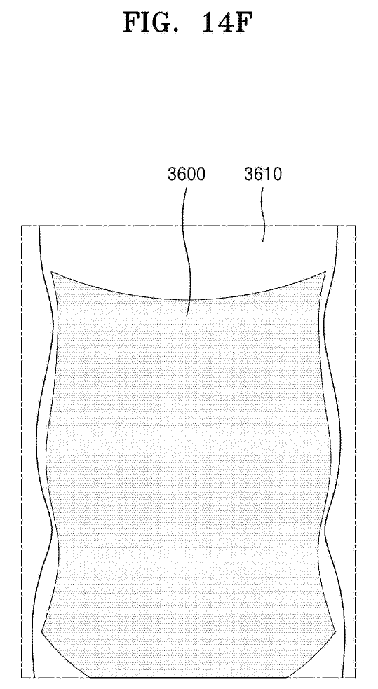

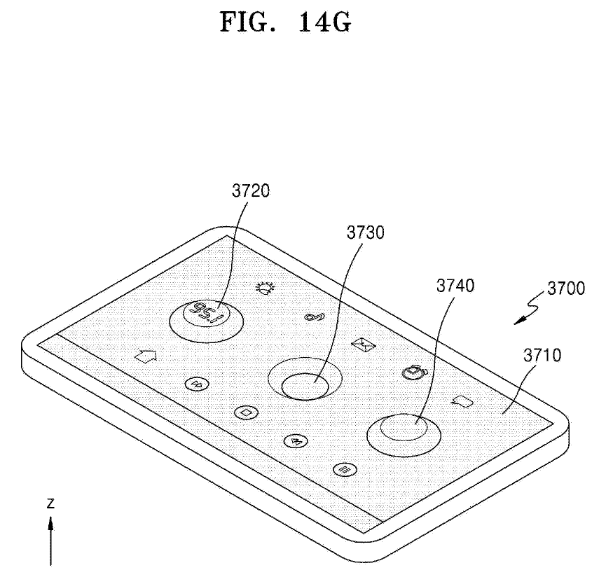

FIGS. 14A to 14G each are schematic perspective views showing embodiments of an electronic device including any one of the display panels described above.

Referring to FIG. 14A, any one of the display panels in the embodiments described above may be used for a wearable electronic device 3100 that is wearable in a part of a user's body. The wearable electronic device 3100 may include a body part 3110 and a display part 3120 provided in the body part 3110. Any one of the display panels in the embodiments described above may be used as the display part 3120 of the wearable electronic device 3100. As illustrated in FIG. 14A, the wearable electronic device 3100 may be deformable. In an embodiment, the wearable electronic device 3100 may be used as a smart watch or a smartphone according to the user's selection.

FIG. 14B illustrates a medical electronic device 3200. In an embodiment, the medical electronic device 3200 may include a body part 3210 and an emission unit 3220. Any one of the display panels in the embodiments described above may be used as the emission unit 3220 of the medical electronic device 3200. The emission unit 3220 may emit light (e.g., infrared, visible light, etc.) of a predetermined wavelength band to the body of a patient. In an embodiment, the body part 3210 may include a stretchable textile material, and may have a structure to be worn on the body of a user using the emission unit 3220.

FIG. 14C illustrates an educational electronic device 3300. In an embodiment, the educational electronic device 3300 may include a display part 3320 provided in a frame 3310. The display part 3320 may use any one of the display panels in the embodiments described above. Images such as a sea with crashing waves, a snow-covered mountain, or a volcano with flowing lava may be provided through the display part 3320, and in this state, the display part 3320 may be stretched in a height direction (e.g., the z direction) by reflecting the height of the waves, the mountain, or the volcano. In some embodiments, a part of the display part 3320 has a height that sequentially varies depending on a direction in which lava flows, thereby showing the movement of lava in three dimensions. The educational electronic device 3300 may include a plurality of pins (or strokes parts 3330) arranged on the rear surface of the display part 3320 to cause the display part 3320 to be stretched in the height direction. As the pins 3330 move in the third direction (e.g., the z direction or the −z direction), the image displayed in the display part 3320 may be implemented to have a height in three dimensions. Although FIG. 14C illustrates an embodiment of the educational electronic device 3300, the use of the device illustrated in FIG. 14C is not limited thereto, and any device capable of providing predetermined image information may be used therefor.

The electronic devices described with reference to FIGS. 14A to 14C may have a variable shape, but the disclosure is not limited thereto. As in the embodiments described below, any one of the display panels in the embodiments described above may be used for electronic devices in which a part (e.g., a screen) for displaying an image is fixed.

FIG. 14D illustrates an embodiment of a robot 3400 as an electronic device. The robot 3400 may recognize a movement or an object by a camera unit 3440, and display a predetermined image to a user through display parts 3420 and 3430. In some embodiments, as any one of the display panels in the embodiments described above is stretchable in various directions as described above, the display panel may be assembled to a body frame having a hemispherical shape, and thus, the robot 3400 may include the display parts 3420 and 3430 that are hemispherical.

FIG. 14EA illustrates an embodiment of a vehicle display device 3500 as an electronic device, and FIG. 14EB is an enlarged view of a portion of the vehicle display device 3500 . The vehicle display device 3500 may include a cluster 3510, a center information display (“CID”) 3520, and/or a passenger display 3530. As any one of the display panels in the embodiments described above is stretchable in various directions, regardless of the shape of an internal frame of a vehicle, the display panel may be used for the cluster 3510, the CID 3520, and/or a passenger display 3530.

Although FIG. 14EA illustrates that the cluster 3510, the CID 3520, and/or the passenger display 3530 are separated from one another, the disclosure is not limited thereto. In another embodiment, two or more components selected from among the cluster 3510, the CID 3520, and/or the passenger display 3530 may be connected integrally.

In some embodiments, the vehicle display device 3500 may include a button 3540 that is capable of displaying a predetermined image. Referring to the enlarged portion of FIG. 14EB, the button 3540 that is hemispherical may include an object 3542 that moves in the z direction or the −z direction and provides a sense of using a button and an electronic device disposed above the object 3542. In some embodiments, when the object 3542 has a three-dimensionally rounded surface, the electronic device may have a three dimensionally further rounded surface.

FIG. 14F illustrates that an electronic device in an embodiment is an electronic device 3600 for advertising or display. In some embodiments, the electronic device 3600 for advertising or display may be installed on a structure 3610 that is fixed, such as a wall or a pillar. When the structure 3610 includes an uneven surface as illustrated in FIG. 14F, the electronic device 3600 for advertising or display may be disposed along the uneven surface of the structure 3610. In some embodiments, the electronic device 3600 for advertising or display may be installed on the structure 3610 by a heat shrink film or the like.

FIG. 14G illustrates that an electronic device in an embodiment is a controller 3700. The controller 3700 may include an image type button. In an embodiment, the controller 3700 may include first to third button areas 3720, 3730, and 3740 as partial areas of a display part 3710 protrude in the z direction or in the −z direction (or recessed in the z direction), for example. In some embodiments, the first and third button areas 3720 and 3740 may protrude in the z direction, and the second button area 3730 may protrude in the −z direction (or recessed in the z direction).

By the embodiments described above, a relatively high elasticity, relatively high resolution display panel, and an electronic device including the same, may be implemented. The scope of the disclosure is not limited by the above effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display panel comprising:
a substrate including:
a plurality of island areas; and
a plurality of bridge areas connecting neighboring island areas among the plurality of island areas to each other;
a plurality of pixels arranged in the plurality of island areas;
a plurality of wires arranged in the plurality of bridge areas;
a first organic layer covering the plurality of pixels, the plurality of wires, and a side surface of the substrate;
a first electrode layer covering an upper surface and a side surface of the first organic layer;
a second organic layer covering an upper surface and a side surface of the first electrode layer; and
a second electrode layer covering an upper surface and a side surface of the second organic layer,
wherein a plurality of first openings overlapping the plurality of pixels in a plan view is defined in the first electrode layer, and
a plurality of second openings overlapping the plurality of pixels in the plan view is defined in the second electrode layer.

2. The display panel of claim 1, wherein the second electrode layer comprises:
a plurality of first electrode cells arranged in a first direction; and
a plurality of second electrode cells arranged in a second direction crossing the first direction, and
the first electrode layer comprises a plurality of connection electrodes connecting neighboring second electrode cells among the plurality of second electrode cells to each other.

3. The display panel of claim 2, wherein, among the plurality of first electrode cells, first electrode cells neighboring in the first direction are provided integrally.

4. The display panel of claim 2, wherein the plurality of first electrode cells and the plurality of second electrode cells are spaced apart from each other.

5. The display panel of claim 2, wherein the connection electrode crosses a first electrode cell of the plurality of first electrode cells, is electrically separated by the second organic layer from the first electrode cell and is electrically connected to overlapping second electrode cells among the plurality of second electrode cells through contact holes that penetrate the second organic layer.

6. The display panel of claim 1, wherein the second electrode layer comprises:
a first part extending along an edge of each of the plurality of island areas in the plan view; and
a second part extending along each of the plurality of bridge areas in the plan view.

7. The display panel of claim 6, wherein the second part is electrically connected to the first electrode layer through a contact hole that penetrates the second organic layer.

8. The display panel of claim 6, wherein a third opening exposing the upper surface of the second organic layer is defined in the second part, and
the second electrode layer further comprises an auxiliary electrode disposed within a second opening among the plurality of second openings and a first auxiliary wire disposed within the third opening.

9. The display panel of claim 8, wherein the first electrode layer further comprises a second auxiliary wire connected to the auxiliary electrode and the first auxiliary wire.

10. The display panel of claim 1, wherein each of the plurality of bridge areas has a meandering shape.

11. A display panel comprising:
a substrate including:
a plurality of island areas; and
a plurality of bridge areas connecting neighboring island areas among the plurality of island areas to each other;
a display layer including:
a plurality of pixels arranged in the plurality of island areas; and
a plurality of wires arranged in the plurality of bridge areas;
an input detection layer covering an upper surface and a side surface of the display layer and including a plurality of first touch electrodes extending in a first direction and a plurality of second touch electrodes extending in a second direction crossing the first direction,
wherein the plurality of first touch electrodes and the plurality of second touch electrodes cover a side surface of the substrate along edges of the plurality of island areas and edges of the plurality of bridge areas, respectively.

12. The display panel of claim 11, wherein each of the plurality of first touch electrodes comprises a plurality of first electrode cells arranged in the first direction,
each of the plurality of second touch electrodes comprises a plurality of second electrode cells arranged in the second direction and a plurality of connection electrodes connecting neighboring second electrode cells among the plurality of second electrode cells, and
the plurality of first electrode cells and the plurality of connection electrodes are arranged in different layers.

13. The display panel of claim 12, wherein, among the plurality of first electrode cells, first electrode cells neighboring in the first direction are provided integrally.

14. The display panel of claim 12, wherein the plurality of first electrode cells and the plurality of second electrode cells are spaced apart from each other.

15. The display panel of claim 12, further comprising an insulating layer disposed between a connection electrode among the plurality of connection electrodes and the plurality of first electrode cells, and between the connection electrode and the plurality of second electrode cells,
wherein the connection electrode crosses a first electrode cell of the plurality of first electrode cells, is electrically separated by the insulating layer and is electrically connected to overlapping second electrode cells among the plurality of second electrode cells through contact holes that penetrate the insulating layer.

16. The display panel of claim 11, wherein each of the plurality of first touch electrodes and each of the plurality of second touch electrodes comprise:
a first part extending along an edge of each of the plurality of island areas; and
a second part extending along each of the plurality of bridge areas.

17. The display panel of claim 16, wherein each of the plurality of second touch electrodes comprises a plurality of electrode cells arranged in the second direction and a connection electrode connecting neighboring electrode cells among the plurality of electrode cells,
the input detection layer further comprises an insulating layer disposed between the connection electrode the plurality of first touch electrodes, and between the connection electrode and the plurality of second touch electrodes, and
the second part of the second touch electrode overlapping the connection electrode among the plurality of second touch electrodes is electrically connected to the connection electrode through a contact hole that penetrates the insulating layer.

18. The display panel of claim 17, wherein a first opening overlapping the plurality of pixels is defined in the first part.

19. The display panel of claim 18, wherein a second opening overlapping the plurality of bridge areas is defined in the second part, and
the input detection layer comprises an auxiliary electrode disposed within the first opening, a first auxiliary wire disposed within the second opening, and a second auxiliary wire connecting the auxiliary electrode to the first auxiliary wire.

20. An electronic device including a display panel that is stretchable, wherein the display panel comprises:
a substrate including a plurality of island areas and a plurality of bridge areas connecting neighboring island areas among the plurality of island areas to each other;
a plurality of pixels arranged in the plurality of island areas;
a plurality of wires arranged in the plurality of bridge areas;
a first organic layer covering the plurality of pixels, the plurality of wires, and a side surface of the substrate;
a first electrode layer covering an upper surface and a side surface of the first organic layer;
a second organic layer covering an upper surface and a side surface of the first electrode layer; and
a second electrode layer covering an upper surface and a side surface of the second organic layer,
wherein a plurality of first openings overlapping the plurality of pixels in a plan view is defined in the first electrode layer, and
a plurality of second openings overlapping the plurality of pixels in the plan view is defined in the second electrode layer.
